(19) United States
(12) Patent Application Publication
(10) Pub. No.: US 2025/0225291 A1
(43) Pub. Date: Jul. 10, 2025

(54) TECHNIQUES FOR ADAPTING A SIMULATION IN A VIRTUAL ENVIRONMENT

(71) Applicant: NVIDIA Corporation, Santa Clara, CA (US)

(72) Inventors: Pratyush Mahapatra, San Bruno, CA (US); Naveen Kumar Rai, Sunnyvale, CA (US); Ruthie D. Lyle, Durham, NC (US)

(21) Appl. No.: 18/406,030

(22) Filed: Jan. 5, 2024

(51) Int. Cl. G06F 30/20

(52) U.S. Cl. CPC G06F 30/20

(57) ABSTRACT

User reaction data is received from one or more user devices of a user. The user reaction data indicates a reaction of the user to a simulation provided via at least one of the user devices. The user reaction data is provided as input to an artificial intelligence (AI) model. Simulation update data is determined based on output(s) of the AI model, the simulation update data indicating one or more updates to the simulation based on an experience of the user in view of the provided user reaction data. A model file associated with the simulation is updated to reflect the one or more updates indicated by the simulation data. The updated model file, when executed, creates a rendering of the updated simulation. The updated simulation is provided to the user via the at least one of the user devices based on an execution of the updated model file.

### TECHNICAL FIELD

At least one embodiment pertains to techniques for adapting a simulation in a virtual environment. For example, user reaction data can be collected from user devices as a user accesses a simulation, the user reaction data indicating an experience of the user during the simulation. The user reaction data can be used to update the simulation based on the experience of the user.

### BACKGROUND

Platforms (or other such computing systems) can provide users with access to simulations of a real-world scenario in a virtual environment. For example, a platform can provide a user with access to a simulated classroom environment, a simulated social environment, etc. In some instances, the simulation can include one or more objects and/or characters that are included in accordance with a task or goal of the simulation. For example, the simulation can be associated with training users to use a particular type of real-world equipment (e.g., aviation equipment, medical equipment, etc.) and/or experience a particular type of real-world environment (e.g., a classroom environment, a conference environment, etc.). A user can engage with the one or more objects and/or the characters of the simulation, in accordance with the task or goal of the simulation. Conventional platforms do not update the simulation based on a reaction of the user (e.g., indicated by biometric data or other such data) and accordingly, the user may not be able to achieve the task or goal of the simulation.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts an illustrative computer system architecture, according to at least one embodiment;

FIG. 2 is a block diagram that includes an example platform and an example simulation engine, according to at least one embodiment;

FIG. 3 is a flow diagram depicting an example method for adapting a simulation in a virtual environment, according to at least one embodiment;

FIG. 4 is a block diagram that includes an example predictive system, according to at least one embodiment;

FIG. 5 depicts an illustrative generative AI system, according to at least one embodiment;

FIG. 6A illustrates inference and/or training logic, according to at least one embodiment;

FIG. 6B illustrates inference and/or training logic, according to at least one embodiment;

FIG. 7 illustrates an example data center system, according to at least one embodiment;

FIG. 8 illustrates a computer system, according to at least one embodiment;

FIG. 9 illustrates a computer system, according to at least one embodiment;

FIG. 10 illustrates at least portions of a graphics processor, according to one or more embodiments;

FIG. 11 illustrates at least portions of a graphics processor, according to one or more embodiments;

FIG. 12 is an example data flow diagram for an advanced computing pipeline, in accordance with at least one embodiment;

FIG. 13 is a system diagram for an example system for training, adapting, instantiating and deploying machine learning models in an advanced computing pipeline, in accordance with at least one embodiment; and

FIGS. 14A and 14B illustrate a data flow diagram for a process to train a machine learning model, as well as client-server architecture to enhance annotation tools with pre-trained annotation models, in accordance with at least one embodiment.

### DETAILED DESCRIPTION OF EMBODIMENTS

Embodiments of the present disclosure relate to techniques for adapting a simulation in a virtual environment. A platform (or other such computing system) can provide users with access to a simulation in a virtual environment. A virtual environment refers to a digital construct that serves as a simulated, computer-generated representation of a physical or imagined space. A simulation refers to a dynamic scenario that unfolds within the virtual environment. Simulations offer users the opportunity to engage, manipulate, and explore these artificially constructed surroundings. A simulation can encompass a wide range of experiences, including lifelike training exercises and realistic physical interactions in a real-world environment. Users can engage or interact with virtual objects or characters of the simulation and can receive feedback from the environment, which can give the user a sense of presence in the virtual environment.

As indicated above, simulations can provide users with access to simulated experiences (e.g., educational experiences, etc.). Some simulated experiences can be associated with a particular goal or task. For example, some simulated experiences can be associated with training users to use a particular type of real-world equipment (e.g., aviation equipment, medical equipment, etc.) and/or experience a particular type of real-world environment (e.g., a classroom environment, a social environment, etc.). In some systems, a simulated experience may be updated or modified for a user based on user interaction with one or more characters or objects in the virtual environment. For example, a virtual environment can include or otherwise represent a classroom environment and can include virtual avatars associated with a teacher and/or students in the virtual classroom environment. Such virtual avatars are referred to as teacher avatars and student avatars, respectively. A simulation provided via the virtual environment can involve a user engaging with the teacher or the students in the virtual classroom environment, with the goal of preparing the user to engage with a teacher and/or students in a real-world classroom environment. The virtual environment can also include a virtual avatar associated with the user accessing the virtual environment (referred to herein as a user avatar). The user can cause their user avatar to engage with the teacher avatar and/or the student avatars (e.g., using a user device), which can include causing their avatar to walk up to the other avatars, causing their avatar to perform one or more actions (e.g., raising their hand, shaking hands with the teacher avatar and/or the student avatars, etc.), providing text or audio (e.g., via the user device) to enable their avatar to communicate with the teacher avatar and/or the student avatar, and so forth. The platform can update the simulation based on the user interaction with the teacher avatar and/or the student avatars. For example, if the user causes their virtual avatar to walk up to a student virtual avatar, the platform can update the simulation to cause the student virtual avatar to face the user's virtual avatar.

Conventional systems only update simulations based on a user interaction with objects or characters in the virtual environment and do not consider a user reaction to the simulated experience when updating the simulation. For instance, a user that is engaging with the characters or objects in the virtual environment may be getting frustrated or overwhelmed with the interactions in the virtual environment. Conventional systems will continue to update the simulations based on the user engagement with the characters or objects and do not consider or account for the user response to the simulation (e.g., frustration, overwhelmingness) when making the update. By only updating simulations based on user interaction, the simulated experience can be rigid or, in some cases, robotic to the user, which can contradict the goal or purpose of the simulation. For instance, if a simulation has a goal or purpose of preparing a user to engage with a teacher and/or students in a real-world environment and the user gets frustrated or overwhelmed with the interactions in the virtual classroom environment (e.g., per the rigidness of the simulation), the user ultimately may not be prepared for or willing to enter the real-world environment and/or may stop engaging with the simulation before the goal or purpose is achieved. In some cases, this can contradict the purpose or goal of the simulation and/or can exacerbate or intensify problems that the simulation was developed to address.

It can take a significant amount of computing resources (e.g., processing cycles, memory space, etc.) to provide a user with access to a simulation. If a goal or purpose of a simulation is not achieved and/or the problems to be addressed by the simulation are exacerbated or intensified by the simulation, such computing resources are wasted (e.g., at the user device, at a remote computing location, etc.) and, in some instances, a larger number of computing resources are consumed (e.g., if the user spends a longer amount of time engaging with the simulation). Such computing resources are therefore made unavailable to other processes of the overall system, which can increase the latency and decrease the efficiency of the computing system.

Embodiments of the present disclosure address the above and other deficiencies by providing techniques for adapting a simulation in a virtual environment based on user reaction data. A platform can provide users with access to a simulation in a virtual environment. The platform can be a three-dimensional (3D) graphics collaboration and/or simulation platform, such as the Omniverse™ Platform by NVIDIA Corporation. In some embodiments, the simulation can be associated with a particular task or goal pertaining to the user. For example, the virtual environment can be a virtual classroom environment and the simulation can be associated with a goal of preparing a user to interact with objects/others in a real-world classroom environment. The virtual environment can include one or more virtual assets (e.g., characters, virtual objects, design elements, etc.) that correspond to the goal or task of the simulation. For example, the virtual classroom environment can include virtual avatars representing a teacher (referred to herein as a teacher avatar) and/or one or more students (referred to herein as student avatars), one or more virtual desk objects, a virtual chalk board/dry erase board, etc.

A user can be associated with one or more user devices, where at least one of the user devices can include sensors configured to collect user reaction data (e.g., facial reaction data, body language data, heart rate data, breathing rate data, speech pattern data, etc.). The sensors of the one or more user devices can include an imaging sensor (e.g., a camera), an audio sensor (e.g., a microphone), one or more biometric sensors (e.g., a heartrate sensor, etc.). The user can access the simulation via at least one of the one or more user devices (e.g., via a user interface (UI) of a user device). As the user accesses and engages with the simulation, the sensors of the one or more user devices can collect user reaction data that indicates a reaction of the user to the simulation. The user device can provide the collected user reaction data to the platform. In some embodiments, the platform can feed the user reaction data as input to an artificial intelligence (AI) model (e.g., a machine learning model) that is trained to predict a user reaction to or user experience with the simulation based on given user reaction data and/or one or more updates to the simulation based on the experience of the user in view of the provided user reaction data. In some embodiments, one or more outputs of the AI model can indicate a particular reaction that the user is having to the simulation (e.g., the user is frustrated, the user is overwhelmed, the user is happy, etc.). In additional or alternative embodiments, the one or more outputs of the AI model can indicate an update to the simulation based on the reaction of the user. In an illustrative example, the one or more outputs of the AI model can indicate that the user is frustrated or overwhelmed when engaging with the teacher avatar and indicate an update to modify the facial expression of the teacher avatar.

The platform can extract one or more updates to the simulation from the one or more outputs of the AI model and can update a model file associated with the simulation to reflect the one or more updates. In accordance with the previous illustrative example, the platform can update a section of the model file that corresponds to a facial expression of the teacher avatar to cause the teacher avatar's facial expression to be modified according to the extracted update. In additional or alternative embodiments, the platform can provide an indication of the one or more updates and/or a model file for the simulation as input to a generative AI model. The generative AI model can generate an updated model file that corresponds to the update to the simulation. Further details regarding updating the model file are provided herein.

Upon updating the model file, the platform can provide the updated model file for execution by a rendering engine residing at the user device and/or a computing system connected to the user device (e.g., via a network). Upon execution of the updated model file, the platform can provide the user with access to the updated simulation via the user device. For example, the platform can, based on the execution of the updated model file, update the facial expression of the teacher avatar to reflect the modification obtained based on the one or more outputs of the AI model. The one or more user devices associated with the user can continue to collect user reaction data, which can indicate a reaction of the user to the updated simulation. The collected user reaction data can be used to continuously update the simulation based on the user reaction, so as to better accomplish the goal or task of the simulation for the user.

In some embodiments, the platform can update one or more goals or tasks of the simulation based on the user reaction data collected by the one or more user devices as the user accesses the simulation. For example, the platform can determine a user reaction to a simulation based on user reaction data collected during the simulation, as indicated above. Based on the determined user reaction, the platform can determine whether a progress of the user with respect to the one or more goals of the simulation is on track (e.g., is as expected or targeted for the simulation) or if the progress of the user falls below or exceeds what is expected or targeted for the simulation. The platform can update the goals or tasks (e.g., by adding additional goals or tasks) and/or can modify a timeline for the goals or tasks, so as to assist the user to achieve or satisfy the goals or tasks according to their skill level or reaction level for the simulation. Further details regarding updating the goals or tasks of the simulation based on user reaction data are described herein.

Aspects and embodiments of the present disclosure provide techniques to enable a platform to update a simulation and/or a goal of a simulation based on user reaction data collected during the simulation. As indicated above, user devices can collect user reaction data as a user engages with one or more objects of the simulation in a virtual environment. The platform can provide the collected user reaction data to a trained AI model to determine one or more updates to be made to the simulation based on the user experience and can update the simulation based on the determined updates. Embodiments of the present disclosure enable a platform to continuously update or modify a simulation based on the user experience, rather than simply based on user interaction with objects of the simulation. By updating the simulation based on the user experience, the platform can adapt the simulation to better suit the user, which can allow the user to more quickly or effectively meet or satisfy the goal or purpose of the simulation. For instance, if the platform detects that the user is frustrated or overwhelmed with interactions in the simulated virtual environment, the platform can update the simulation to modify objects in the environment so to calm the user, thus helping the user to meet the goal or purpose of the simulation and/or improving the overall experience of the user. As embodiments of the present disclosure enable the user to meet the goal or purpose of the simulation, computing resources that are consumed to provide the user with access to the simulation are not wasted. In some instances, embodiments of the present disclosure can enable a user to meet the goal or purpose of the simulation in a shorter time period, which can reduce the amount of computing resources consumed in the computing system. Such computing resources can be made available for other processes of the system, which can increase the efficiency and decrease the efficiency of the computing system.

The systems and methods described herein may be used for a variety of purposes, by way of example and without limitation, these purposes may include systems or applications for online multiplayer gaming, machine control, machine locomotion, machine driving, synthetic data generation, model training, perception, augmented reality, virtual reality, mixed reality, robotics, security and surveillance, autonomous or semi-autonomous machine applications, deep learning, environment simulation, data center processing, conversational AI, light transport simulation (e.g., ray tracing, path tracing, etc.), collaborative content creation for 3D assets, digital twin systems, cloud computing and/or any other suitable applications.

Disclosed embodiments may be comprised in a variety of different systems such as systems for participating on online gaming, automotive systems (e.g., a control system for an autonomous or semi-autonomous machine, a perception system for an autonomous or semi-autonomous machine), systems implemented using a robot, aerial systems, medial systems, boating systems, smart area monitoring systems, systems for performing deep learning operations, systems for performing simulation operations, systems implemented using an edge device, systems incorporating one or more virtual machines (VMs), systems for performing synthetic data generation operations, systems implemented at least partially in a data center, systems for performing conversational AI operations, systems for performing light transport simulation, systems for performing collaborative content creation for 3D assets, systems for generating or maintaining digital twin representations of physical objects, systems implemented at least partially using cloud computing resources, and/or other types of systems.

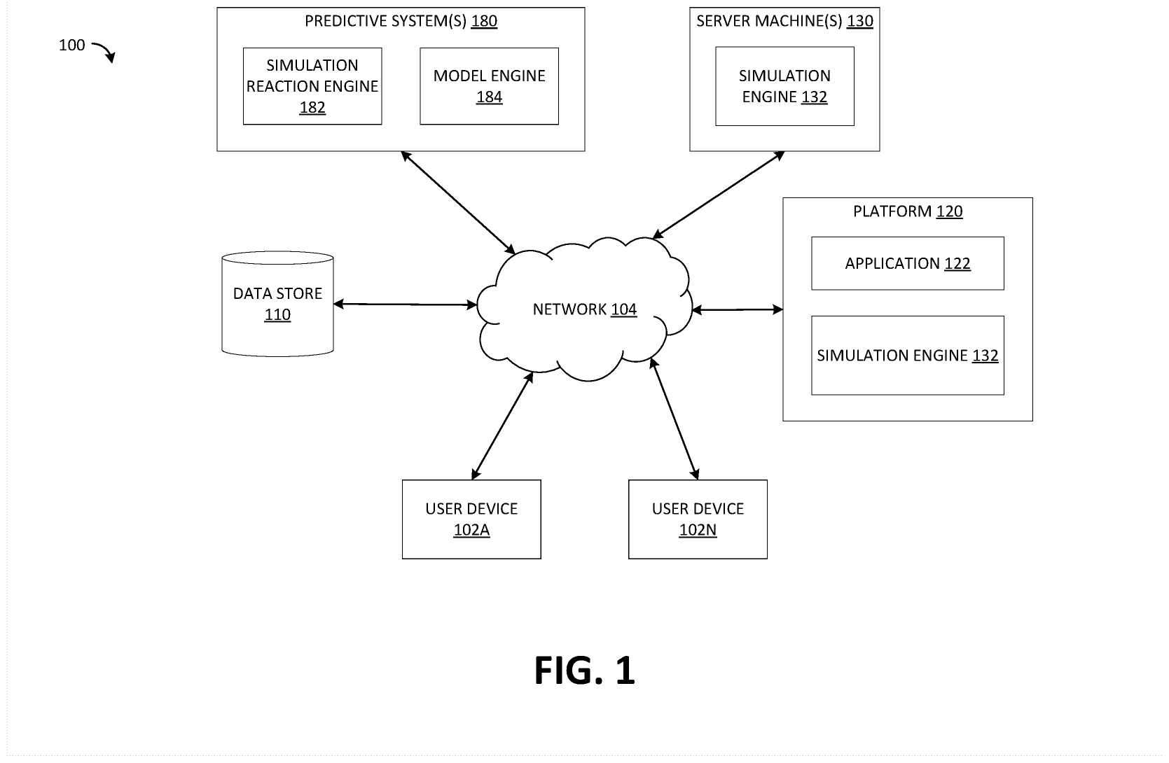

FIG. 1 depicts an illustrative computer system architecture, according to aspects of the present disclosure. The system architecture 100 (also referred to as “system” herein) includes one or more client devices 102, a data store 110, a platform 120, one or more server machines 130, and/or a predictive system 180, each connected to a network 104. In implementations, network 104 may include a public network (e.g., the Internet), a private network (e.g., a local area network (LAN) or wide area network (WAN)), a wired network (e.g., Ethernet network), a wireless network (e.g., an 802.11 network or a Wi-Fi network), a cellular network (e.g., a Long Term Evolution (LTE) network), routers, hubs, switches, server computers, and/or a combination thereof.

In some implementations, data store 110 is a persistent storage that is capable of storing data as well as data structures to tag, organize, and index the data. Data store 110 can be hosted by one or more storage devices, such as main memory, magnetic or optical storage based disks, tapes or hard drives, NAS, SAN, and so forth. In some implementations, data store 110 can be a network-attached file server, while in other embodiments data store 110 can be some other type of persistent storage such as an object-oriented database, a relational database, and so forth, that may be hosted by platform 120 or one or more different machines coupled to the platform 120 via network 104.

Client device(s) 102 (collectively and individually referred to herein as user device 102) refers to any device (or software that executes using a device) that requests access to data and/or a service provided by a computing service (e.g., platform 120). In some embodiments, user device 102 may include computing devices such as personal computers (PCs), laptops, mobile phones, smart phones, tablet computers, netbook computers, network-connected televisions, etc. In other or similar embodiments, client devices 102 can include or be connected to a virtual reality (VR) device (e.g., a VR headset) that is configured to provide a VR experience to a user of platform 120 and/or platform 140. The VR device can be a monolithic VR device (e.g., a VR headset that includes a dedicated processor and/or power source) or another type of VR device, in some embodiments. In some implementations, client devices 102A-N may also be referred to as “client devices.” User device 102 may include a content viewer. In some implementations, a content viewer may be an application that provides a user interface (UI) for users to view or upload content, such as images, video items, web pages, documents, etc. For example, the content viewer may be a web browser that can access, retrieve, present, and/or navigate content (e.g., web pages such as Hyper Text Markup Language (HTML) pages, digital media items, etc.) served by a web server. The content viewer may render, display, and/or present the content to a user. The content viewer may also include an embedded media player (e.g., a Flash® player or an HTML5 player) that is embedded in a web page (e.g., a web page that may provide information about a product sold by an online merchant). In another example, the content viewer may be a standalone application (e.g., a mobile application or app) that allows users to view digital media items (e.g., digital video items, digital images, electronic books, etc.).

In some embodiments, platform 120 can provide users (e.g., of client devices 102) with access to one or more applications 122. In some embodiments, users of platform 120 can access the features and functionalities of application 122 via an application instance running using a user device 102. An application instance refers to a collection or grouping of resources used to execute features and functionalities of application 122 via user device 102. In an illustrative example, an application instance can include a portion or segment of instructions (e.g., code) associated with application 122 that is executed by computing resources of user device 102 to provide a user with access to the features or functionalities of application 122. Multiple client devices 102 can execute the instructions to provide respective users with access to the application 122 (e.g., simultaneously). Each instance of application 122 provided via a user device 102 can be isolated from other application instances provided via other client devices, in some embodiments.

In some embodiments, application 122 can enable users to access a simulation in a virtual environment. A virtual environment, as described herein, refers to a digital representation of a physical or imagined space. A virtual environment can include one or more virtual assets, such as characters, objects, design elements, etc. A simulation refers to a dynamic scenario that unfolds within the virtual environment. Some simulations are associated with a particular goal or task pertaining to a user accessing the simulation. For example, virtual environment can include a virtual classroom environment. A simulation within the virtual classroom environment can be associated with a goal or purpose of preparing a user to enter a real-world classroom environment. Accordingly, the virtual environment can include one or more assets (e.g., teacher avatars, student avatars, desk objects, chalkboard/whiteboard objects, etc.) associated with the classroom environment. A user can interact with the one or more assets in the virtual environment, in accordance with the simulation. In some embodiments, platform 120 can provide users with access to avatars (e.g., teacher avatars, student avatars, etc.) and/or other assets using features or functionality of an avatar engine, such as Avatar Cloud Engine™ by NVIDIA Corporation.

Platform 120 can provide users with access to a simulation of application 122 (e.g., via a user device 102). In some embodiments, platform 120 can be or can otherwise correspond to a 3D graphics collaboration and/or simulation platform, such as the Omniverse™ Platform by NVIDIA Corporation. A user of user device 102 can access a simulation of application 122 via an instance of application 122 running via a respective user device 102, in some embodiments. As illustrated in FIG. 1, platform 120 can include a simulation engine 132 that facilitates user access to a simulation of application 122. A user of a user device 102 can request access to a simulation (e.g., by engaging with one or more UI elements of a UI), and user device 102 can forward the request to platform 120 (e.g., via network 104). Upon receiving the request, simulation engine 132 can identify one or more model files (e.g., stored at data store 110), associated with the simulation. A model file refers to a collection of data and/or instructions that, when executed by a rendering engine, generates a rendering of one or more 3D objects of a virtual scene. In some embodiments, model files can include instructions pertaining to an animation of the one or more 3D objects (e.g., according to a simulation within the virtual environment). Simulation engine 132 can provide the identified one or more model files to a rendering engine (e.g., at user device 102, at a remote computing device of system 100, etc.), and the rendering engine can execute the one or more model files.

In some embodiments, the one or more model files (or other data associated with rendering the simulation) can be associated with a universal scene description (USD) format (e.g., openUSD format). The USD format can be tailored specifically for avatar and asset animation and can allow for enhanced and efficient representation of complex 3D scenes. The USD format provides mechanisms for asset referencing, variant management, and non-destructive animation.

Upon execution of the one or more model files, a rendering of the one or more 3D objects and/or the animation of the 3D object(s) are generated and provided for presentation to the user (e.g., via a UI of user device 102). The user can access the simulation in the virtual environment based on the presented animation of the rendered 3D objects. In some embodiments, the user can engage (e.g., click, tap, select, etc.) with one or more UI elements of the UI to interact with the rendered 3D objects, in accordance with the simulation. For example, the rendered virtual environment can include a virtual avatar associated with the user and/or a teacher avatar in a virtual classroom environment. The user can engage with one or more UI elements to cause the user virtual avatar to walk up to and/or engage with the teacher avatar.

As the user accesses the simulation, one or more user devices 102 associated with the user can collect user reaction data that indicates a reaction of the user to the simulation. In some embodiments, at least one user device 102 can correspond to or otherwise include a computer device (e.g., a laptop computer, etc.) that includes an imaging sensor (e.g., a camera) and/or an audio sensor (e.g., a microphone). As the user accesses the simulation, the imaging sensor and/or the audio sensor can collect image data and/or audio data that indicates the user reaction to the simulation. In an illustrative example, collected image data can depict a facial expression and/or body language of the user as the user engages with the simulation. In another illustrative example, collected audio data can indicate audio provided by the user as the user engages with the simulation (e.g., verbal phrases, breathing patterns, etc.). In some embodiments, a user device 102 can include one or more biometric sensors that are configured to collect biometric data (e.g., heart rate data, blood oxygen level data, etc.). Such biometric sensors can collect the biometric data as the user engages with the simulation (e.g., in accordance with a functionality of the biometric sensors). It should be noted that, in some embodiments, multiple user devices 102 can collect user reaction data during the simulation. For example, the user can access the simulation via a laptop computer or a VR headset. Sensors of the laptop computer or the VR headset can collect user reaction data according to the capabilities or functionalities of the sensors of or connected to the laptop computer or the VR headset. In some instances, the user can wear a wearable device (e.g., a smart watch) that includes one or more biometric sensors. The biometric sensors of the wearable device can collect user reaction data simultaneously (or approximately simultaneously) with the laptop computer or the VR headset, as the user accesses the simulation. User reaction data can include, but is not limited to, facial reaction data (e.g., indicated by image data), body language data (e.g., indicated by image data), heart rate data (e.g., indicated by biometric data), breathing rate data (e.g., indicated by audio data and/or other biometric data), speech pattern data (e.g., indicated by audio data), and so forth.

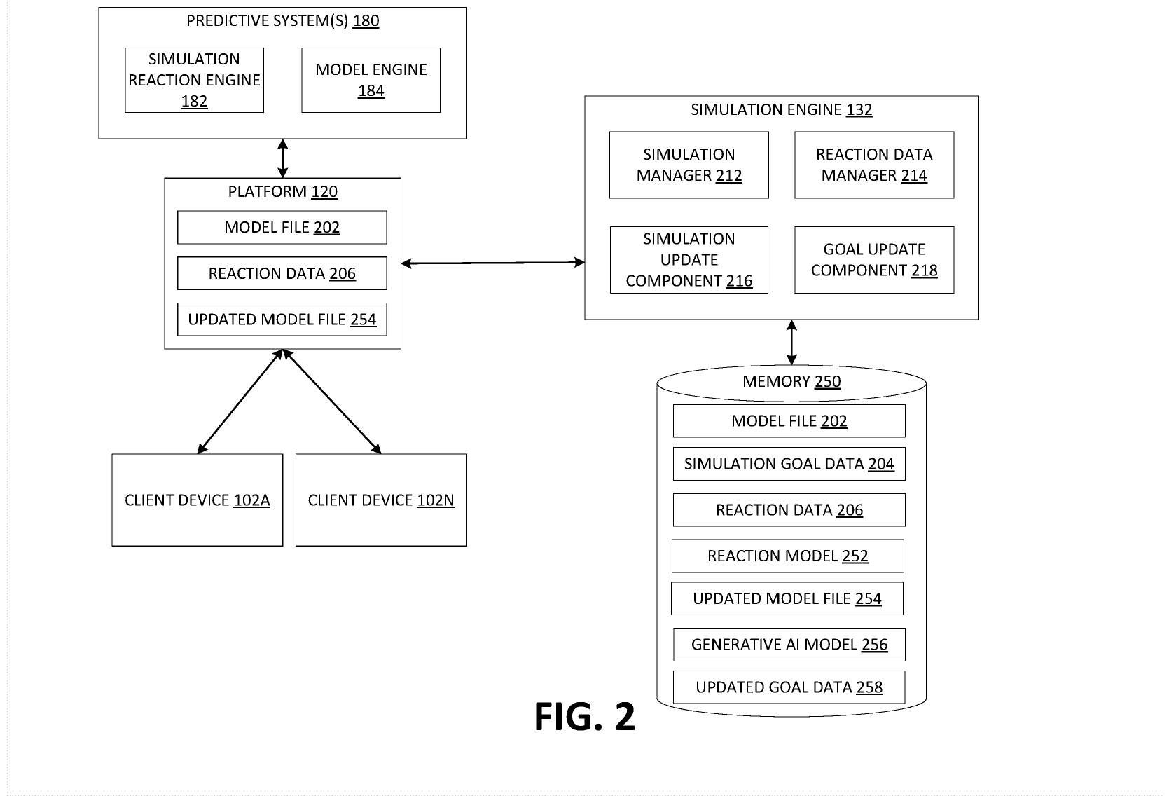

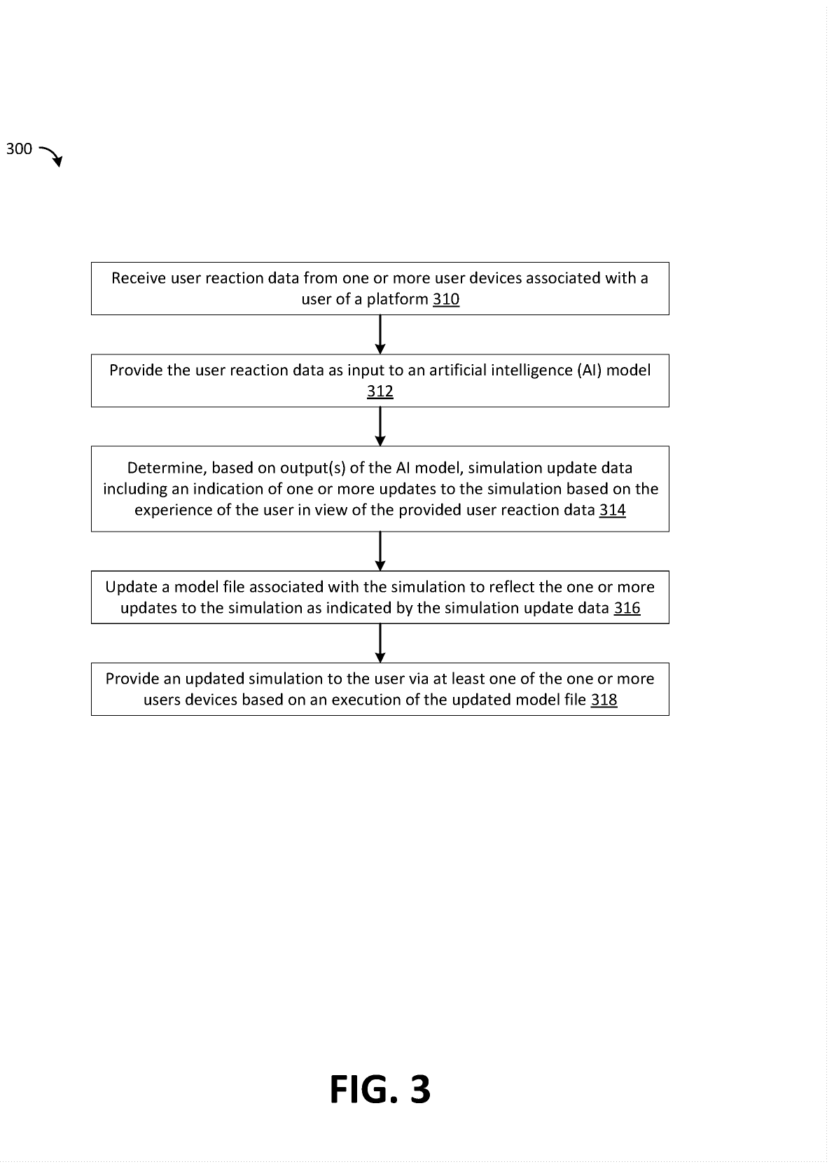

As indicated above, user device(s) 102 can collect user reaction data and can provide the user reaction data to platform 120. Simulation engine 132 can update a model file associated with the simulation based on the user reaction data, as described herein. In some embodiments, simulation engine 132 can forward the user reaction data to a simulation reaction engine 182 and/or a model engine 184 of predictive system 180. Simulation reaction engine 182 and/or model engine 184 can be associated with one or more artificial intelligence (AI) models that are trained to predict a reaction or an experience of the user during the simulation and, in some embodiments, an update to be made to the simulation in view of the user reaction or experience. Simulation engine 132 of platform 120 can determine one or more updates to be made to model files of the simulation based on outputs of the one or more AI models and can update the model files in accordance with the determination, in some embodiments. Simulation engine 132 can provide the updated model files to a rendering engine to obtain an updated rendering of the simulation, in accordance with the determined update, and can provide the updated rendering to the user via a user device 102. Further details regarding simulation reaction engine 182, model engine 184, and updating the model files for the simulation are provided below with respect to FIGS. 2-3.

In some embodiments, user reaction data can be obtained using one or more engines (e.g., of platform 120) accessible via a user device 102 and/or platform 120. For example, user reaction data can be obtained using a speech recognition engine or techniques, such as that of Riva by NVIDIA Corporation. In another example, user reaction data can be obtained using tools or techniques associated with a natural language processing transformer, such as that of NeMo Megatron™ by NVIDIA Corporation.

As indicated above, simulation engine 132 can provide a user with access to an updated simulation, which has been updated based on user reaction data collected by user devices 102. User devices 102 can continuously collect user reaction data as the user engages with the simulation (and/or the updated simulation) and simulation engine 132 can, in some instances, continuously update the simulation based on the collected user reaction data.

As indicated above, in some embodiments, a simulation is associated with a goal or a purpose pertaining to the user. In some embodiments, simulation engine 132 can update the goal or purpose based on the collected user reaction data, in accordance with embodiments described herein.

It should be noted that although FIG. 1 illustrates simulation engine 132 as part of platform 120, in additional or alternative embodiments, simulation engine 132 can reside on one or more server machines that are remote from platform 120. For example, simulation engine 132 can reside at server machine 130. Further, although FIG. 1 illustrates simulation reaction engine 182 and model engine 184 as part of predictive system 180, in additional or alternative embodiments, simulation reaction engine 182 and/or model engine 184 can reside on platform 120, server machine(s) 130, user device 102, and/or any other component of system 100. It should be noted that in some other implementations, the functions of platform 120, server machine 130, and/or predictive system(s) 180 can be provided by more or a fewer number of machines. For example, in some implementations, components and/or modules of platform 120, server machine 130, and/or predictive system(s) 180 may be integrated into a single machine, while in other implementations components and/or modules of any of platform 120, server machine 130, and/or predictive system(s) 180 may be integrated into multiple machines. In addition, in some implementations, components and/or modules of server machine 130, and/or predictive system(s) 180 into platform 120.

In general, functions described in implementations as being performed platform 120, server machine 130, and/or predictive system(s) 180 can also be performed on the user device 102 in other implementations. In addition, the functionality attributed to a particular component can be performed by different or multiple components operating together. Platform 120 can also be accessed as a service provided to other systems or devices through appropriate application programming interfaces, and thus is not limited to use in websites.

In implementations of the disclosure, a “user” can be represented as a single individual. However, other implementations of the disclosure encompass a “user” being an entity controlled by a set of users and/or an automated source. For example, a set of individual users federated as a community in a social network can be considered a “user.” Further to the descriptions above, a user may be provided with controls allowing the user to make an election as to both if and when systems, programs, or features described herein may enable collection of user information (e.g., information about a user's social network, social actions, or activities, profession, a user's preferences, or a user's current location), and if the user is sent content or communications from a server. In addition, certain data can be treated in one or more ways before it is stored or used, so that personally identifiable information is removed. For example, a user's identity can be treated so that no personally identifiable information can be determined for the user, or a user's geographic location can be generalized where location information is obtained (such as to a city, ZIP code, or state level), so that a particular location of a user cannot be determined. Thus, the user can have control over what information is collected about the user, how that information is used, and what information is provided to the user.

FIG. 2 is a block diagram that includes an example platform 120 and an example simulation engine 132, according to aspects of the present disclosure. As described above, simulation engine 132 can reside at or can otherwise be connected to platform 120 (e.g., using network 104). In some embodiments, platform 120 and/or simulation engine 132 can be connected to memory 250. Memory 250 can correspond to one or more portions of data store 110, in some embodiments. In additional or alternative embodiments, memory 250 can correspond to any memory of, connected to, or accessible by a component of system 100.

As described above, simulation engine 132 can facilitate and/or manage user access to simulations in virtual environments. As illustrated in FIG. 2, simulation engine 132 can include a simulation manager 212, a reaction data manager 214, a simulation update component 216, and/or a goal update component 218. Embodiments pertaining to simulation engine 132 are described, at least, with respect to FIGS. 2-3 herein.

FIG. 3 is a flow diagram depicting an example method 300 for adapting a simulation in a virtual environment, according to aspects of the present disclosure. In some embodiments, method 300 can be performed by platform 120 and/or one or more components of or connected to platform 120. For example, one or more operations of method 300 can be performed by simulation engine 132, in some embodiments. Method 300 may be performed by one or more processing units (e.g., CPUs and/or GPUs), which may include (or communicate with) one or more memory devices. In at least one embodiment, method 300 may be performed by multiple processing threads (e.g., CPU threads and/or GPU threads), each thread executing one or more individual functions, routines, subroutines, or operations of the method. In at least one embodiment, processing threads implementing method 300 may be synchronized (e.g., using semaphores, critical sections, and/or other thread synchronization mechanisms). Alternatively, processing threads implementing method 300 may be executed asynchronously with respect to each other. Various operations of method 300 may be performed in a different order compared with the order shown in FIG. 3. Some operations of the methods may be performed concurrently with other operations. In at least one embodiment, one or more operations shown in FIG. 3 may not always be performed.

At block 310, processing logic receives user reaction data from one or more user devices associated with a user of a platform. As indicated above, platform 120 can provide a user with access to a simulation in a virtual environment. In some embodiments, a user can be associated with one or more user devices 102. A user device 102 can include any device that enables a user to access a simulation in a virtual environment and/or can collect user reaction data indicating a user reaction during the simulation. A user associated with a user device 102 can request access to a simulation by engaging with one or more UI elements of a UI of the user device 102, in some embodiments. Upon receiving the user request, user device 102 can forward the request to platform 120 (e.g., via network 104). Simulation manager 212 can identify one or more model files 202 associated with the requested simulation upon receiving the request from user device 102. In some embodiments, memory 250 can include or can otherwise correspond to a data store that stores model files 202 associated with simulations available to users of platform 120. In some embodiments, a simulation designer or developer can provide a model file 202 for a simulation to platform 120 (e.g., via a user device 102 or other such client device). In some embodiments, model file 202 can be associated with the USD format, as described above. The simulation designer or developer can additionally or alternatively provide simulation goal data 204, which indicates a goal or a purpose associated with the simulation. In some embodiments, simulation manager 212 can update the data store to include the provided model file 202. The data store can include or can otherwise be associated with a data structure that includes one or more entries each corresponding to a respective simulation offered by platform 120. Simulation manager 212 can update an entry of the data structure to include the model file 202 and/or a pointer (e.g., a memory address) to a region of memory 250 that stores the model file 202. In some embodiments, simulation manager 212 can further update the entry to include (or otherwise reference) simulation goal data 204 associated with the simulation.

In some embodiments, the simulation goal data 204 for a simulation can indicate a general or overall goal or purpose of the simulation. For example, the indicated goal or purpose for a simulation in a virtual classroom environment can be to prepare a user to enter or interact with others in a real-world classroom environment. In other or similar embodiments, simulation goal data 204 can indicate actions that are to be performed in the simulation in order for the goal to be achieved and/or an expected timeline for performing each action in accordance with the overall goal. In accordance with the prior example, the simulation goal data 204 can indicate that, in order to achieve the overall goal of preparing a user to enter or interact with others in a real-world classroom environment, the user must meet one or more criteria associated with interacting with the teacher avatar in the virtual environment, such as saying hello to the teacher avatar while maintaining calm and without getting frustrated. In another example, the simulation goal data 204 can indicate that to achieve the overall goal of the simulation, the user must meet one or more criteria associated with interacting with one or more virtual objects in the virtual environment, such as identifying a pencil virtual object in the virtual environment. The simulation goal data 204 can also indicate a timeline or expected time period for the user to meet the one or more criteria associated with interacting with the teacher avatar and/or the one or more virtual objects.

As described above, simulation manager 212 can receive a request from a user device 102 to access a simulation. Upon receiving the request, simulation manager 212 can identify a model file 202 associated with the simulation from the data store of memory 250 and can provide the model file 202 to a rendering engine (not shown) associated with user device 102 and/or platform 120. In some embodiments, the rendering engine can reside at user device 102. Accordingly, simulation manager 212 can provide the model file 202 to user device 102 (e.g., via network 104). In other or similar embodiments, the rendering engine can reside at a computing device that is remote from user device 102 (e.g., a remote server). Simulation manager 212 can provide the model file 202 to the remote server. Upon receiving the model file 202, the rendering engine can execute the model file 202 to generate the rendering of the 3D objects in the virtual environment and/or the animation of the rendered 3D objects, in accordance with the simulation. The rendering engine can present the rendering and/or the animation to the user via a UI of user device 102.

In some embodiments, the UI of user device 102 can include one or more UI elements that enable the user to engage with assets or objects of the simulation. For example, the UI can include one or more UI elements associated with each object of the simulation. The user can engage with a respective UI element to engage with the object (e.g., in accordance with the simulation). For example, a virtual teacher avatar in a virtual classroom environment can include one or more UI elements that, when selected or engaged by the user, can enable the user to interact with the virtual teacher avatar. In other or similar embodiments, the user can interact with virtual assets of the virtual environment using one or more peripheral devices (e.g., a mouse, a keyboard, a microphone, a joystick, etc.) of or connected to user device 102.

One or more user devices 102 can collect user reaction data during the simulation. As described above, one or more user devices 102 can include sensors that are configured to collect data indicative of a reaction of the user as the user interacts with characters and/or objects of the simulation. The sensors can include image sensors (e.g., a camera), audio sensors (e.g., a microphone), biometric sensors (e.g., a heart rate sensor), and so forth. User reaction data can include, but is not limited to, facial recognition data, body language data, heart rate data, breathing rate data, speech pattern data, and so forth. Upon collecting the user reaction data, the one or more user devices 102 can provide the collected data to platform 120 (depicted as reaction data 206 of FIG. 2). Reaction data manager 214 of simulation engine 132 can store the reaction data 206 at memory 250, in some embodiments.

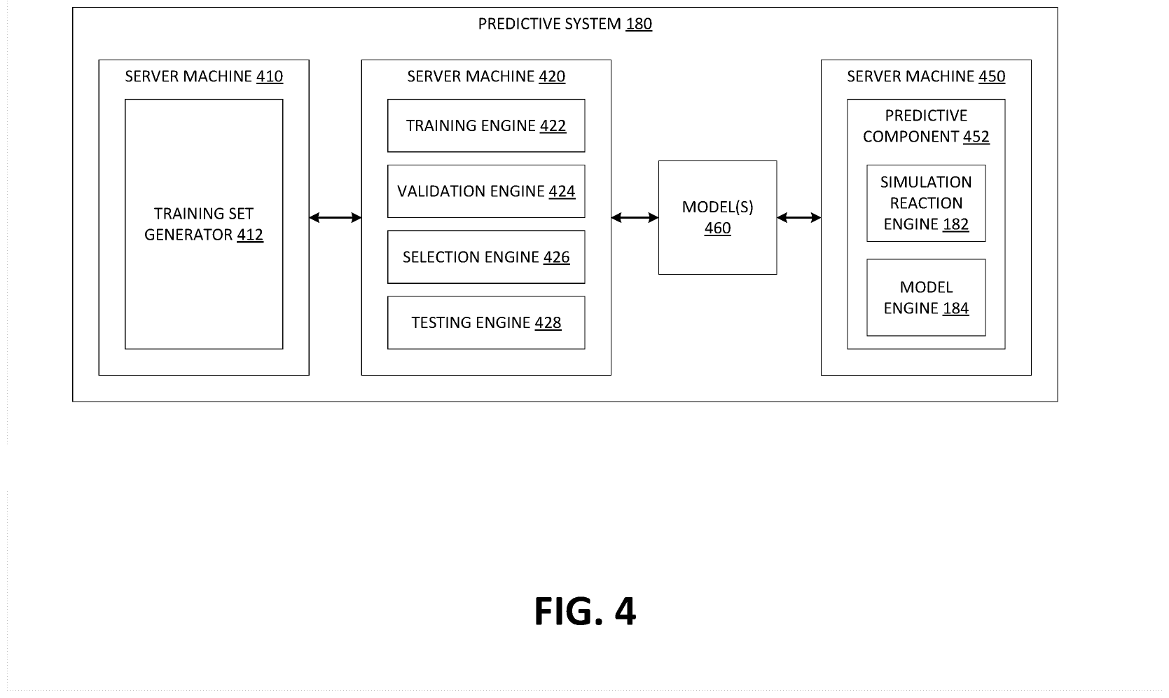

Referring back to FIG. 3, at block 312, processing logic provides the user reaction data as input to an artificial intelligence (AI) model. In some embodiments, reaction data manager 214 can provide reaction data 206 to simulation reaction engine 182 of predictive system 180. Simulation reaction engine 182 can be configured to obtain data that characterizes a user reaction or a user experience during a simulation provided by platform 120. In some embodiments, simulation reaction engine 182 can feed the reaction data 206 received from reaction data manager 214 as input to an artificial intelligence (AI) model that is trained to predict a reaction or experience that a user is having during a simulation. Such model is referred to herein a reaction model 252. In additional or alternative embodiments, reaction model 252 can be further trained to predict an update to a model file 202 based on the given reaction data 206. Reaction model 252 can be trained based on historical data associated with at least one of the one or more user devices 102 associated with the user, in some embodiments. In other or similar embodiments, reaction model 252 can be additionally or alternatively trained based on historical data associated with a set of other user devices 102 associated with other users of the platform. In some embodiments, the update may be predicted by the model 208 to cause the user to have a different user reaction or experience (e.g., in accordance with the goal or purpose of the simulation). Details regarding training of the reaction model 252 are provided with respect to FIG. 4 below.

At block 314, processing logic determines, based on one or more outputs of the AI model, simulation update data including an indication of one or more updates to the simulation based on the experience of the user in view of the provided user reaction data. The one or more updates to the simulation can include an audio update, a visual update, a virtual avatar manipulation, an object manipulation, a virtual environment manipulation, and so forth. In some embodiments, the simulation update data can correspond to the USD format. As indicated above, simulation reaction engine 182 can feed reaction data 206 as input to the reaction model 252 and can obtain one or more outputs of the reaction model 252. In some embodiments, the one or more outputs of the reaction model 252 can indicate one or more user reactions (e.g., anger, frustration, happiness, etc.) and, for each indicated reaction, a level of confidence that the respective reaction corresponds to the reaction data 206 fed as input. Simulation reaction engine 182 can identify a user reaction of the one or more outputs having a level of confidence that satisfies one or more criteria (e.g., exceeds a threshold level of confidence, is larger than levels of confidence for other user reactions, etc.) and can extract the identified user reaction from the one or more outputs.

As indicated above, reaction model 252 can be further or alternatively trained to predict one or more updates to a model file 202 based on given reaction data 206. The one or more outputs of reaction model 252 can indicate one or more updates to the model file 202 and, for each indicated update, a level of confidence that the respective update will cause a user to have a target reaction or a reaction in accordance with the goal or purpose of the simulation. Simulation reaction engine 182 can identify an update of the one or more outputs having a level of confidence that satisfies one or more criteria (e.g., exceeds a threshold level of confidence, is larger than levels of confidence for other user reactions, etc.) and can extract the identified update from the one or more outputs.

At block 316, processing logic updates a model file associated with the simulation to reflect the one or more updates to the simulation indicated by the simulation update data. Upon obtaining a user reaction and/or an update to model file 202 based on one or more outputs of reaction model 252, simulation update component 216 can provide the user reaction and/or the update obtained by simulation reaction engine 182 to model engine 184. Model engine 184 can be configured to update a model file 202, in some embodiments. As indicated above, the one or more outputs of reaction model 252 can include an indication of an update to the model file 202. For example, indicated update can be to replace a reference to an audio file associated with a voice of a teacher avatar to correspond to a different audio file (e.g., associated with a calming voice). In some embodiments, model engine 184 can update the model file 202 according to the indicated update and can provide the updated model file (e.g., updated model file 254) to platform 120. As illustrated in FIG. 2, the updated model file 254 can be stored at memory 250. Updated model file 254 can have the USD format, in some embodiments.

In other or similar embodiments, model engine 184 can update the model file 202 based on a set of rules associated with the simulation. For example, a developer or designer of the simulation can provide to platform 120 a set of rules (not shown) that indicate one or more modifications to be made to a simulation in view of a user reaction during the simulation. An example rule can be if the user appears to be frustrated or overwhelmed, the simulation is to be updated to cause the virtual teacher avatar to have a calming voice or a friendly facial expression. Model engine 184 can identify a rule of the set of rules that corresponds to the user reaction obtained based on outputs of reaction model 252 and can update the model file 202 for the simulation in accordance with the identified rule. In accordance with the previous example, model engine 184 can update the model file to replace a reference to an audio file associated with a voice of the teacher avatar to correspond to a different audio file (e.g., associated with a calming voice). Model engine 184 can additionally or alternatively update the model file by modifying one or more instructions associated with an animation of the teacher avatar to cause the teacher avatar to have a friendly facial expression.

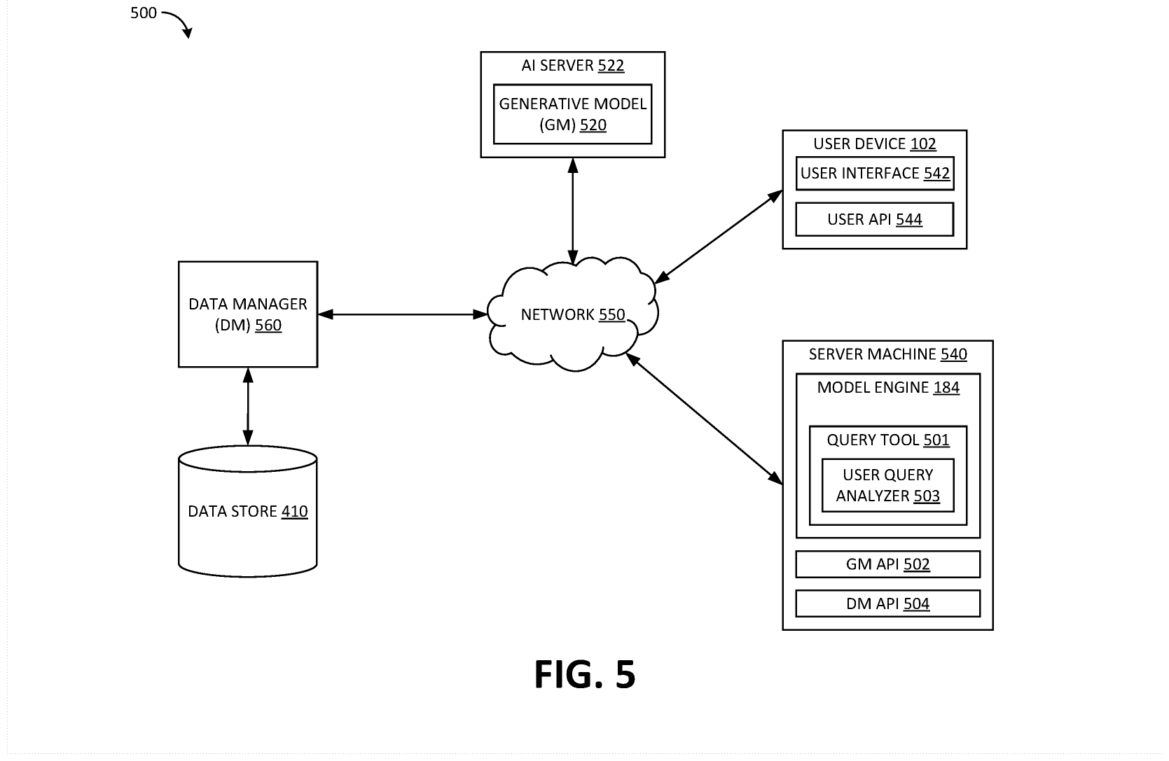

In other or similar embodiments, model engine 184 can feed the user reaction and/or the update to model file 202 (e.g., with model file 202) to a generative AI model 256 that is trained to generate an updated model file 254 based on a given user reaction and/or a given update to a model file 202. In some embodiments, the generative AI model 256 can be an AI model that is trained to generated new, original data based on given inputs. Further details regarding generative AI model 256 and training the generative AI model 256 are provided below with respect to FIGS. 4-5. Upon providing the user reaction and/or the update to the model file 202 as input to the generative AI model 256, model engine 184 can obtain one or more outputs of the model 256. The one or more outputs can include, in some embodiments, an updated model file 254 that reflects the changes indicated by the update and/or one or more changes according to the user reaction. In an illustrative example, the user reaction determined for the simulation can indicate that the user is frustrated with the simulation and, in some embodiments, can indicate that the user is frustrated with a vantage point of a virtual avatar associated with the user with respect to other characters or objects in the virtual environment. Model engine 184 can feed the indicated user reaction as input to the generative AI model 256, as described above. The updated model file 254 can include updated data and/or updated instructions that, when executed by a rendering engine, cause a vantage point of the virtual avatar to be modified so to better suit the user (e.g., to calm the user). In another illustrative example, the predicted update to the model file 202 obtained based on outputs of the reaction model 252 can indicate a modification to a vantage point of a virtual avatar associated with the user, as described above. The generative AI model 256 can generate updated model file 254 to reflect the update, as described above.

It should be noted that although embodiments of the present disclosure describe the user reaction and/or update being determined based on outputs of a different model (e.g., reaction model 252) than generative AI model 256. However, in some embodiments, user reaction data 206 can be fed directly to generative AI model 256 for prediction/determination of the user reaction/recommended update, as described above. In other or similar embodiments, reaction model 252 can be or can otherwise include a generative AI model 256 that is configured to generate an updated model file 254 associated with the simulation, as described above.

In other or similar embodiments, model engine 184 can feed the indicated user reaction as input to one or more additional AI models (not shown) such as a discriminative model or another type of model. In some embodiments, the additional AI models may not include generative model. The additional AI models may predict, based on given user reaction data for a simulation, one or more modifications to the simulation according to a goal or objective of the simulation. Model engine 184 can obtain one or more outputs of the additional AI models, which can indicate one or more modifications to the simulation based on the given user reaction data, and can update or otherwise generate the updated model file 254 based on the one or more outputs. In some embodiments, the one or more additional AI models can include or otherwise correspond to Maxine™ by NVIDIA Corporation.

At block 318, processing logic provides an updated simulation to the user via at least one of the one or more user devices based on an execution of the updated model file. Simulation update component 216 can obtain the updated model file 256 from model engine 184 and can provide the updated model file 256 to the rendering engine (not shown) for execution to generate the updated simulation. For example, simulation update component 216 can provide the updated model file 256 to user device 102 (e.g., via network 104). A rendering engine of user device 102 can execute the updated model file 256 to generate the rendering of the updated simulation. The user device 102 can provide the user with access to the updated simulation, as described herein. In another example, simulation update component 21 can provide the updated model file 256 to a rendering engine of a remote computing device and the rendering engine can execute the updated model file 256 to generate the rendering of the updated simulation. The remote computing device can provide the generated rendering to user device 102 (e.g., via network 104) and the user device 102 can present the updated rendering of the simulation to the user, as described above.

In accordance with previously described embodiments, user device(s) 102 can continue to collect reaction data 206 that indicates a user reaction to the updated simulation. Platform 120 can continuously feed the collected reaction data 206 to the reaction model 252 and can continuously update simulation based on the one or more outputs of reaction model 252, as described herein.

In some embodiments, goal update component 218 can update a goal or purpose of a simulation based on user reaction data 206. As described above, simulation goal data 204 can indicate a goal or a purpose associated with a simulation. In some instances, simulation goal data 204 can indicate actions that are to be performed in the simulation in order for the goal to be achieved and/or an expected timeline for performing each action in accordance with the overall goal. In some embodiments, goal update component 218 can compare a user's progress in the simulation indicated actions and/or expected timeline to determine whether the user's progress satisfies one or more progress criteria (e.g., the user is on track or approximately on track to perform/satisfy the actions of the simulation according to the timeline). The user's progress can be indicated by user progress data (not shown) that indicates one or more actions performed by the user and/or a time period during which such actions were performed. The user's progress can satisfy the progress criteria if a difference between the actions/time period of the user progress data and the actions/timeline of the simulation goal data 204 falls below a threshold difference. Upon determining that the user's progress satisfies the progress criteria, goal update component 218 may not update the goal or purpose of the simulation.

Upon determining that the user's progress does not satisfy the progress criteria (e.g., the difference meets or exceeds a threshold difference), goal update component 218 can update the goal or purpose of the simulation based on the user reaction data 206. In some embodiments, goal update component 218 can update the goal or purpose of the simulation based on a set of rules associated with the goal or purpose of the simulation. For example, a developer or designer of the simulation can provide (e.g., with the model file 202) a set of rules indicating one or more modifications to the goals of the simulation that are to be made based on the collected user reaction data 206. An example rule can include if the user is determined to be frustrated for a threshold amount of time while interacting with a teacher avatar (e.g., regardless of the updates to the simulation as described above), the amount of time that the user is to spend interacting with the teacher avatar during a current simulation session is reduced and/or the user is to be faced with a different interaction protocol with respect to the teacher avatar. In some embodiments, goal update component 218 can update the simulation goal data 204 based on the set of rules and the collected reaction data 206 and can store the updated simulation goal data at memory 250 as updated simulation goal data 258.

In other or similar embodiments, goal update component 218 can update the goal or purpose of the simulation based on one or more outputs of an AI model (not shown). The AI model can be trained to predict, based on user reaction data 206, one or more updates to simulation goal data 204. Such AI model is referred to herein as a simulation goal model. Upon feeding the user reaction data 206 to the simulation goal model, goal update component 218 can obtain one or more outputs. The one or more outputs can indicate one or more updates to the simulation goal data 204 and, for each update, a level of confidence that the update will enable the user to meet the overall goal/purpose of the simulation. Goal update component 218 can identify an update of the one or more outputs that has a level of confidence that satisfies one or more confidence criteria (e.g., meets a threshold level of confidence, is larger than levels of confidence for other updates, etc.). Goal update component 218 can update the simulation goal data 204 based on the identified update, as described above.

In some embodiments, simulation update component 216 may further update a simulation based on the updated simulation goal data 258. For example, in some embodiments, simulation update component 216 can provide the updated simulation goal data 258 to model engine 184 and model engine 184 can update the model file 202 for the simulation based on the updated simulation goal data 258. In an illustrative example, the updated simulation goal data 258 can indicate that an amount of time that a user is to interact with a teacher avatar during the simulation session should be reduced. Model engine 184 can update instructions of model file 202 associated with the animation of the teacher avatar to reduce the amount of time that the teacher avatar is presented during the simulation. The updated instructions can be included in updated model file 254, as described above.

In other or similar embodiments, simulation manager 212 can update a simulation protocol (not shown) for the simulation based on the updated simulation goal data 258. For example, the updated simulation goal data 258 can indicate that a maximum time period for a simulation session for the user is increased or decreased. Simulation manager 212 can update the simulation protocol for the simulation to extend or reduce the amount of time that the user is enabled to engage with the simulation based on the updated simulation goal data 258.

In some embodiments, goal update component 218 can provide a user with an indication of the updated simulation goal data 258. For example, goal update component 218 can provide the updated goal data 258 to user device 102. User device 102 can present the updated goal data 258 to a user of user device 102 via a UI of user device 102, in accordance with previously described embodiments.

FIG. 4 is a block diagram that includes an example predictive system 180, according to aspects of the present disclosure. In some embodiments, predictive system 180 can be configured to train one or more machine learning models 460 associated with simulation engine 132. For example, predictive system 180 can be configured to train reaction model 252, generative AI model 256, and/or a simulation goal model.

As illustrated in FIG. 4, predictive system 180 can include a training set generator 412 (e.g., residing at server machine 410), a training engine 412, a validation engine 424, a selection engine 426, and/or a testing engine 428 (e.g., each residing at server machine 420), and/or a predictive component 452 (e.g., residing at server machine 450). Training set generator 412 may be capable of generating training data (e.g., a set of training inputs and a set of target outputs) to train model 460. Machine learning models 460 can include one or more LLMs, as described above, or any other type of machine learning model that is trained to perform tasks pertaining to the above described embodiments.

As mentioned above, training set generator 412 can generate training data for training model 460. Training set generator 412 obtain training data for training model 460 and can organize or otherwise group the training data for training model 460 (e.g., according to the purpose of the model). In some embodiments, training set generator 412 can initialize a training set T (e.g., for training a respective model 460) to null (e.g., { }). In an illustrative example, training set generator 412 can generate training data for training reaction model 252 by obtaining user reaction data (e.g., facial reaction data, body language data, heart rate data, breathing rate data, speech pattern data, etc.) collected for one or more users of platform 120 and obtaining data characterizing a user reaction or a user experience of the user of platform 120 (e.g., at a time period during which the obtained user reaction data was collected). The data characterizing the user reaction or the user experience can be provided by a developer or operator associated with application 122 (or another application of platform 120), a developer or designer of a simulation associated with the obtained user reaction data, and/or a user of application 122 (or the other application) that engaged with the simulation. The obtained user reaction data and/or characterization data can be associated with a single user that has accessed the simulation and/or multiple users that have each accessed the simulation (e.g., via respective user devices 102). Training set generator 412 can generate an input/output mapping. The input can be based on the obtained user reaction data and the output can include the data characterizing the user reaction or the user experience. Training set generator 412 can add the input/output mapping to the training set T and can determine whether training set T is sufficient for training model 460. Training set T can be sufficient for training model 460 if training set T includes a threshold amount of input/output mappings, in some embodiments. In response to determining that training set T is not sufficient for training, training set generator 412 can identify additional data pertaining to a user reaction to a simulation of platform 120 can generate additional input/output mappings based on the additional data. In response to determining that training set T is sufficient for training, training set generator 412 can provide training set T to train model 460. In some embodiments, training set generator 412 provides the training set T to training engine 422.

In additional or alternative embodiments, the input of the input/output mapping can additionally or alternatively indicate the user reaction data collected for the user during a time period during which the user accessed a simulation. The output of the input/output mapping can additionally or alternatively indicate a modification made to the simulation (e.g., by the platform 120 and/or in accordance with a goal or purpose of the simulation, as described above) during the time period. Training set generator 412 can add the input/output mapping to the training set T, as described above.

In another illustrative example, training set generator 412 can generate training data to train generative AI model 256. In such example, training set generator 412 can initialize a training sct T to null (e.g., { }). Training set generator 412 can obtain data associated with one or more user-provided queries to platform 120 and/or one or more responses to the queries. The responses to the queries can include model files or images generated in response to the user-provided queries, in some embodiments. Training set generator 412 can generate an input/output mapping. The input can be based on a user-provided query and the output can indicate the response to the user-provided query. Training set generator 412 can add the input/output mapping to the training set T and can determine whether training set T is sufficient for training model 460. Training set T can be sufficient for training model 460 if training set T includes a threshold amount of input/output mappings, in some embodiments. In response to determining that training set T is not sufficient for training, training set generator 412 can identify additional data that indicates additional phrases provided by users of platform 120 can generate additional input/output mappings based on the additional data. In response to determining that training set T is sufficient for training, training set generator 412 can provide training set T to train model 460. In some embodiments, training set generator 412 provides the training set T to training engine 422. In additional or alternative embodiments, generative AI model 256 can be trained according to embodiments described with respect to FIG. 5.

In yet another illustrative example, training set generator 412 can generate training data for training a simulation goal model by obtaining user reaction data (e.g., facial reaction data, body language data, heart rate data, breathing rate data, speech pattern data, etc.) collected for one or more users of platform 120 during a time period which the users accessed a simulation of platform 120. Training set generator 412 can further obtain simulation goal data indicating one or more goals of the simulation. Training set generator 412 can generate training data including a mapping between the obtained user reaction data and the obtained simulation goal data. In some embodiments, the mapping can be an input/output mapping, as described above, where the input includes the obtained simulation goal data and the output includes the obtained simulation goal data and/or a change of the simulation goal data over the time period. Training set generator 412 can add the mapping to the training set T and can determine whether training set T is sufficient for training model 460. Training set T can be sufficient for training model 460 if training set T includes a threshold number of mappings, in some embodiments. In response to determining that training set T is not sufficient for training, training set generator 412 can identify additional data pertaining to a user reaction to a simulation of platform 120 and one or more goals of the simulation can generate additional mappings based on the additional data. In response to determining that training set T is sufficient for training, training set generator 412 can provide training set T to train model 460. In some embodiments, training set generator 412 provides the training set T to training engine 422.

Training engine 422 can train a machine learning model 460 using the training data (e.g., training set T) from training set generator 412. The machine learning model 460 can refer to the model artifact that is created by the training engine 422 using the training data that includes training inputs and/or corresponding target outputs (correct answers for respective training inputs). The training engine 422 can find patterns in the training data that map the training input to the target output (the answer to be predicted), and provide the machine learning model 460 that captures these patterns. The machine learning model 460 can be composed of, e.g., a single level of linear or non-linear operations (e.g., a support vector machine (SVM or may be a deep network, i.e., a machine learning model that is composed of multiple levels of non-linear operations). An example of a deep network is a neural network with one or more hidden layers, and such a machine learning model may be trained by, for example, adjusting weights of a neural network in accordance with a backpropagation learning algorithm or the like. In one aspect, the training set is obtained by training set generator 412 hosted by server machine 410.

Validation engine 424 may be capable of validating a trained machine learning model 460 using a corresponding set of features of a validation set from training set generator 412. The validation engine 424 may determine an accuracy of each of the trained machine learning models 460 based on the corresponding sets of features of the validation set. The validation engine 424 may discard a trained machine learning model 460 that has an accuracy that does not meet a threshold accuracy. In some embodiments, the selection engine 426 may be capable of selecting a trained machine learning model 460 that has an accuracy that meets a threshold accuracy. In some embodiments, the selection engine 426 may be capable of selecting the trained machine learning model 460 that has the highest accuracy of the trained machine learning models 460.

The testing engine 428 may be capable of testing a trained machine learning model 460 using a corresponding set of features of a testing set from training set generator 412. For example, a first trained machine learning model 460 that was trained using a first set of features of the training set may be tested using the first set of features of the testing set. The testing engine 428 may determine a trained machine learning model 460 that has the highest accuracy of all of the trained machine learning models based on the testing sets.

As described above, predictive system 180 can be configured to train a large language model. It should be noted that predictive system 180 can train the large language model in accordance with embodiments described herein and/or in accordance with other techniques for training a large language model. For example, large language model may be trained on a large amount of data, including prediction of one or more missing words in a sentence, identification of whether two consecutive sentences are logically related to each other, generation of next texts based on prompts, etc.

Predictive component 452 of server machine 450 may be configured to feed data as input to model 460 and obtain one or more outputs. As illustrated in FIG. 4, predictive component 552 can include simulation reaction engine 182 and/or model engine 184. Simulation reaction engine 182 can feed reaction data 204 as input to reaction model 252, as described above, and obtain one or more outputs, which can indicate a reaction or experience of a user during a simulation and/or an update to be made to the simulation based on the user reaction or experience. Model engine 184 can feed the indicated reaction or experience or the user and/or the update to be made to the simulation as input to generative AI model 256, as described herein, and can obtain one or more outputs, which can include an updated model file for the simulation.

FIG. 5 illustrates a high-level component diagram of an example system architecture 500 for a generative AI model 520, in accordance with one or more aspects of the disclosure. The system architecture 500 (also referred to as “system” herein) includes a data store 510, a generative model 520 provided by AI server 522, a server machine 540 with a query tool (QT) 501, one or more client devices 102, and/or other components connected to a network 550. In some embodiments, system 500 can be a part of or can be included in predictive system 180, as described above. In additional or alternative embodiments, client device(s) 102 can correspond to or can include client devices 102, as described with respect to FIG. 1. Network 550 can correspond to network 104 of FIG. 1 and/or can correspond to another network, as described herein.

The system architecture 500 (also referred to as “system” herein) includes an AI server 522 including a generative model (GM) 520 (also referred to herein as a generative AI model). GM 520 can be or can otherwise correspond to generative AI model 256, described with respect to FIG. 2. A generative AI model can include an AI model that is trained to generate new, original data based on given inputs. GM 520 can be trained according based on a corpus of data, as described herein.

A generative AI model can deviate from a machine learning model based on the generative AI model's ability to generate new, original data, rather than making predictions based on existing data patterns. As described above, a generative AI model can include a generative adversarial network (GAN) and/or a variational autoencoder (VAE). In some instances, a GAN, a VAE, and/or other types of generative AI models can employ a different approach to training and/or learning the underlying probability distribution of training data, compared to some machine learning models. For instance, a GAN can include a generator network and a discriminator network. The generator network attempts to produce synthetic data samples that are indistinguishable from real data, while the discriminator network seeks to correctly classify between real and fake samples. Through this iterative adversarial process, the generator network can gradually improve its ability to generate increasingly realistic and diverse data.

Generative AI models also have the ability to capture and learn complex, high-dimensional structures of data. One aim of generative AI models is to model underlying data distribution, allowing them to generate new data points that possess the same characteristics as training data. Some machine learning models (e.g., that are not generative AI models) focus on optimizing specific prediction of tasks.

As mentioned above, GM 520 can be trained to determine the context of a given input text through its ability to analyze and understand surrounding words, phrases, and patterns within the given input text. The training set generator can identify or otherwise obtain sentences (or parts of sentences) of phrases provided by users of platform 120, in some embodiments. The (e.g., audio phrases, textual phrases, etc.) phrases can be provided based on a user interaction with application instance 201 via user device 102. The phrases can be included in content produced or retrieved from other sources of the Internet and/or any other database accessible by the training set generator and/or GM 520. The training set generator can generate an input/output mapping based on the obtained sentences (or parts of sentences). The input can include a portion of an obtained sentence of a phrase. Another portion of the obtained sentence or phrase is not included in the input. The output can include the complete sentence (or part of the sentence), which includes both the portion included in the input and the additional portion that is not included in the input. In accordance with embodiments of the present disclosure, the training set generated by the training set generator to train GM 520 can include a significantly large amount of input/output mappings (e.g., millions, billions, etc.). In some embodiments, multiple input/output mappings of the training set can correspond to the same sentence (or part of the sentence), where the input of each of the input/output mappings include a different portion of the sentence (or part of the sentence).

In some embodiments, the sentences used to generate the input/output mapping of the training set can be obtained from phrases included in electronic documents (e.g., collaborative electronic documents, web page documents, etc.). In such embodiments, the training set generator can determine a context of one or more portions of content of an electronic document. For example, the training set generator can provide a portion of content as input to another machine learning model that is trained to predict a context of the content. the training set generator can update an input/output mapping corresponding to the sentence included in the electronic document to include the determined context. In other or similar embodiments, the training set generator can update the input/output mapping for the sentence to include an indicator of the electronic document (e.g., a pointer or link to the document, a memory address or a web address for the electronic document).

It should be noted that AI server 522 can train the GM 520 in accordance with embodiments described herein and/or in accordance with other techniques for training a large language model. For example, GM 520 may be trained on a large amount of data, including prediction of one or more missing words in a sentence, identification of whether two consecutive sentences are logically related to each other, generation of next texts based on prompts, etc.

In some embodiments, data store 510 (database, data warehouse, etc.) may store any suitable raw and/or processed data, e.g., content data 512. System 500 may further include a data manager (DM) 560 that may be any application configured to manage data transport to and from data store 510, e.g., retrieval of data and/or storage of new data, indexing data, arranging data by user, time, type of activity to which the data is related, associating the data with keywords, and/or the like. DM 560 may collect data associated with various user activities, e.g., data pertaining to a user interaction with UI elements of application instance 201, other applications, internal tools, and/or the like. DM 560 may collect, transform, aggregate, and archive such data in data store 510. In some embodiments, DM 560 may support a suitable software that, with user's consent, resides on client device(s) 102 and tracks user activities. For example, the DM-supported software may capture user-generated content and convert the captured content into a format that can be used by various content destinations. In some embodiments, the DM-supported software may be a code snippet integrated into user's browsers/apps and/or websites visited by the user. Generating, tracking, and transmitting data may be facilitated by one or more libraries of DM 560. In some embodiments, data may be transmitted using messages in the JSON format. A message may include a user digital identifier, a timestamp, name and version of a library that generated the message, page path, user agent, operating system, settings. A message may further include various user traits, which should be broadly understood as any contextual data associated with user's activities and/or preferences. DM 560 may track different ways the same user DM 560 may facilitate data suppression/deletion in accordance with various data protection and consumer protection regulations. DM 560 may validate data, convert data into a target format, identify and eliminate duplicate data, and/or the like. DM 560 may aggregate data, e.g., identify and combine data associated with a given user in the user's profile (user's persona), and storing the user's profile on a single memory partition. DM 560 may scan multiple user's profiles to identify and group users that are related to the same organization, activity, interests, and/or the like. DM 560 may scan numerous user's actions and identify user's profiles associated with multiple uses of a particular resource (e.g., a virtual meeting). DM may ensure reliable delivery of data from user profiles (user personas) to recipients of that data, e.g., by tracking and re-delivering (re-routing) data whose transmission failed.

Data store 510 may be implemented in a persistent storage capable of storing files as well as data structures to perform identification of data, in accordance with embodiments of the disclosure. Data store 510 may be hosted by one or more storage devices, such as main memory, magnetic or optical storage disks, tapes, or hard drives, network-attached storage (NAS), storage area network (SAN), and so forth. Although depicted as separate from the server machine 520, data store 510 may be part of server machine 520, and/or other devices. In some embodiments, data store 510 may be implemented on a network-attached file server, while in other embodiments data store 510 may be implemented on some other types of persistent storage, such as an object-oriented database, a relational database, and so forth, that may be hosted by a server machine 520 or one or more different machines coupled to server machine 520 via network 505.

Server machine 540 may include QT 501 configured to perform automated identification and facilitate retrieval of relevant and timely contextual information for quick and accurate processing of user queries by generative model 520, as disclosed herein. In some embodiments, QT 501 may be implemented by model engine 184. It can be noted that a user's request for an operation pertaining to a virtual asset can be formed into a query that uses QT 501 in some embodiments. Via network 550, QT 501 may be in communication with one or more client devices 102, AI server 522, and data store 510, e.g., via DM 560. Communications between QT 501 and AI server 522 may be facilitated by GM API 502. Communications between QT 501 and data store 510/DM 560 may be facilitated by DM API 504. Additionally, GM API 502 may translate various queries generated by QT 501 into unstructured natural-language format and, conversely, translate responses received from generative model 520 into any suitable form (including any structured proprietary format as may be used by QT 501). Similarly, DM API 504 may support instructions that may be used to communicate data requests to DM 560 and formats of data received from data store 510 via DM 560.

A user may interact with QT 501 via a UI 542 of user device 102. UI 542 may support any suitable types of user inputs, e.g., content from one or more UI elements, speech inputs (captured by a microphone), text inputs (entered using a keyboard, touchscreen, or any pointing device), camera (e.g., for recognition of sign language), and/or the like, or any combination thereof. UI 542 may further support any suitable types of outputs, e.g., speech outputs (via one or more speaker), text, graphics, and/or sign language outputs (e.g., displayed via any suitable screen), file for a word editing application, and/or the like, or any combination thereof. In some embodiments, UI 542 may be a web-based UI (e.g., a web browser-supported interface), a mobile application-supported UI, or any combination thereof. UI 542 may include selectable items. In some embodiments, UI 542 may allow a user to select from multiple (e.g., specialized in particular knowledge areas) generative models 520. UI 542 may allow the user to provide consent for QT 501 and/or generative model 520 to access user data previously stored in data store 510 (and/or any other memory device), process and/or store new data received from the user, and the like. UI 542 may allow the user to withhold consent to provide access to user data to QT 501 and/or generative model 520. In some embodiments, user inputs entered via UI 542 may be communicated to QT 501 via a user API 544. In some embodiments, UI 542 and user API 544 may be located on user device 102 that the user is using to QT 501. For example, an API package with user API 544 and/or user interface 542 may be downloaded to user device 102. The downloaded API package may be used to install user API 544 and/or user interface 542 to enable the user to have two-way communication with QT 501.

QT 501 may include a user query analyzer 503 to support various operations of this disclosure. For example, user query analyzer 503 may receive a user input, e.g., user query, and generate one or more intermediate queries to generative model 520 to determine what type of user data GM 520 might need to successfully respond to user input. Upon receiving a response from GM 520, user query analyzer 503 may analyze the response, form a request for relevant contextual data for DM 560, which may then supply such data. User query analyzer 503 may then generate a final query to GM 520 that includes the original user query and the contextual data received from DM 560. In some embodiments, user query analyzer 503 may itself include a lightweight generative model that may process the intermediate query (ies) and determine what type of contextual data may have to be provided to GM 520 together with the original user query to ensure a meaningful response from GM 520.

QT 501 may include (or may have access to) instructions stored on one or more tangible, machine-readable storage media of server machine 530 and executable by one or more processing devices of server machine 530. In one embodiment, QT 501 may be implemented on a single machine (e.g., as depicted in FIG. 5). In some embodiments, QT 501 may be a combination of a client component and a server component. In some embodiments QT 501 may be executed entirely on the client device(s) 102. Alternatively, some portion of QT 501 may be executed on a client computing device while another portion of QT 501 may be executed on server machine 530.

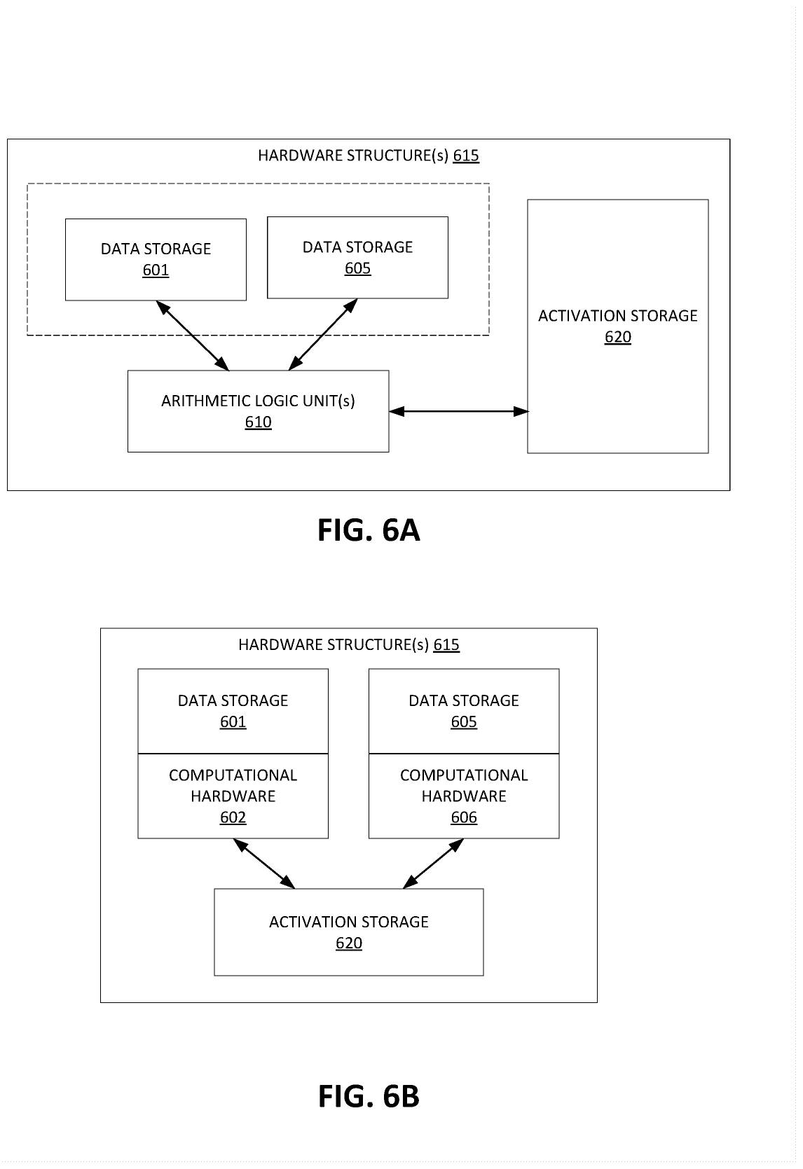

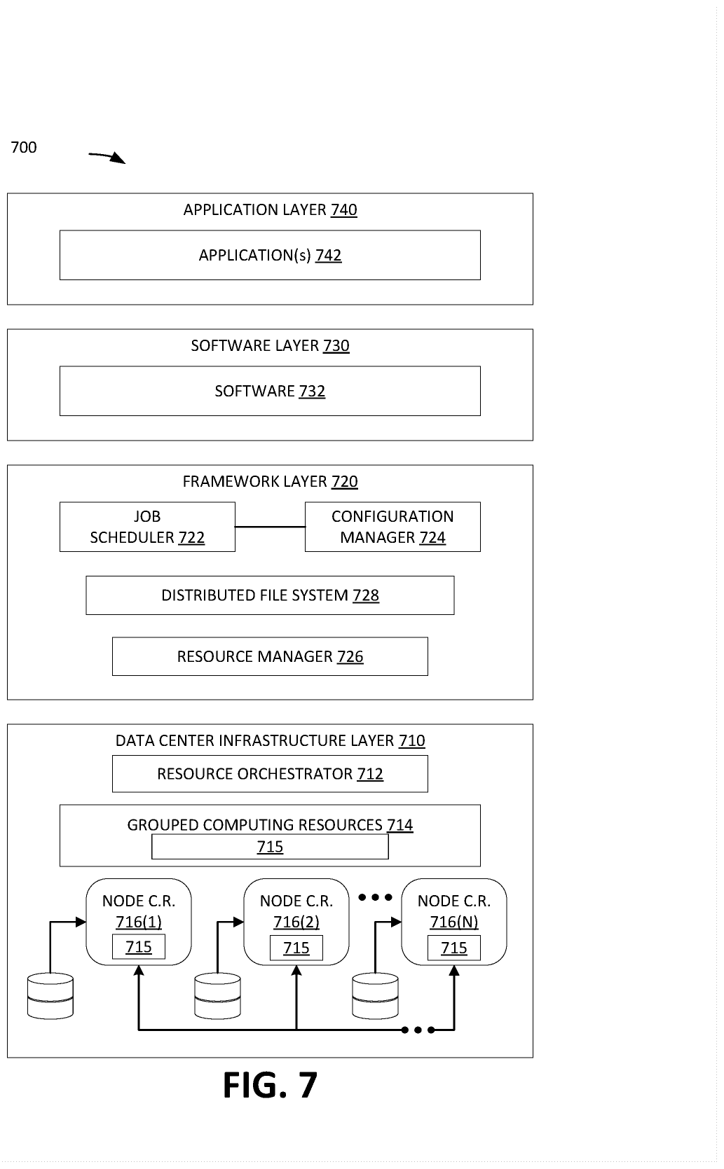

FIG. 6A illustrates hardware structure(s) 615 for inference and/or training logic used to perform inferencing and/or training operations associated with one or more embodiments. Details regarding inference and/or training logic are provided below in conjunction with FIGS. 6A and/or 6B.

In at least one embodiment, hardware structure(s) 615 may include, without limitation, code and/or data storage 601 to store forward and/or output weight and/or input/output data, and/or other parameters to configure neurons or layers of a neural network trained and/or used for inferencing in aspects of one or more embodiments. In at least one embodiment, training logic may include, or be coupled to code and/or data storage 601 to store graph code or other software to control timing and/or order, in which weight and/or other parameter information is to be loaded to configure, logic, including integer and/or floating point units (collectively, arithmetic logic units (ALUs). In at least one embodiment, code, such as graph code, loads weight or other parameter information into processor ALUs based on an architecture of a neural network to which the code corresponds. In at least one embodiment, code and/or data storage 601 stores weight parameters and/or input/output data of each layer of a neural network trained or used in conjunction with one or more embodiments during forward propagation of input/output data and/or weight parameters during training and/or inferencing using aspects of one or more embodiments. In at least one embodiment, any portion of code and/or data storage 601 may be included with other on-chip or off-chip data storage, including a processor's L1, L2, or L3 cache or system memory.

In at least one embodiment, any portion of code and/or data storage 601 may be internal or external to one or more processors or other hardware logic devices or circuits. In at least one embodiment, code and/or code and/or data storage 601 may be cache memory, dynamic randomly addressable memory (“DRAM”), static randomly addressable memory (“SRAM”), non-volatile memory (e.g., Flash memory), or other storage. In at least one embodiment, choice of whether code and/or code and/or data storage 601 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors.

In at least one embodiment, hardware structure(s) 615 may include, without limitation, a code and/or data storage 605 to store backward and/or output weight and/or input/output data corresponding to neurons or layers of a neural network trained and/or used for inferencing in aspects of one or more embodiments. In at least one embodiment, code and/or data storage 605 stores weight parameters and/or input/output data of each layer of a neural network trained or used in conjunction with one or more embodiments during backward propagation of input/output data and/or weight parameters during training and/or inferencing using aspects of one or more embodiments. In at least one embodiment, training logic may include, or be coupled to code and/or data storage 605 to store graph code or other software to control timing and/or order, in which weight and/or other parameter information is to be loaded to configure, logic, including integer and/or floating point units (collectively, arithmetic logic units (ALUs). In at least one embodiment, code, such as graph code, loads weight or other parameter information into processor ALUs based on an architecture of a neural network to which the code corresponds. In at least one embodiment, any portion of code and/or data storage 605 may be included with other on-chip or off-chip data storage, including a processor's L1, L2, or L3 cache or system memory. In at least one embodiment, any portion of code and/or data storage 605 may be internal or external to on one or more processors or other hardware logic devices or circuits. In at least one embodiment, code and/or data storage 605 may be cache memory, DRAM, SRAM, non-volatile memory (e.g., Flash memory), or other storage. In at least one embodiment, choice of whether code and/or data storage 605 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors.

In at least one embodiment, code and/or data storage 601 and code and/or data storage 605 may be separate storage structures. In at least one embodiment, code and/or data storage 601 and code and/or data storage 605 may be same storage structure. In at least one embodiment, code and/or data storage 601 and code and/or data storage 605 may be partially same storage structure and partially separate storage structures. In at least one embodiment, any portion of code and/or data storage 601 code and/or data storage 605 may be included with other on-chip or off-chip data storage, including a processor's L1, L2, or L3 cache or system memory.

In at least one embodiment, hardware structure(s) 615 may include, without limitation, one or more arithmetic logic unit(s) (“ALU(s)”) 610, including integer and/or floating point units, to perform logical and/or mathematical operations based, at least in part on, or indicated by, training and/or inference code (e.g., graph code), a result of which may produce activations (e.g., output values from layers or neurons within a neural network) stored in an activation storage 620 that are functions of input/output and/or weight parameter data stored in code and/or data storage 601 and/or code and/or data storage 605. In at least one embodiment, activations stored in activation storage 620 are generated according to linear algebraic and or matrix-based mathematics performed by ALU(s) 610 in response to performing instructions or other code, wherein weight values stored in code and/or data storage 605 and/or code and/or data storage 601 are used as operands along with other values, such as bias values, gradient information, momentum values, or other parameters or hyperparameters, any or all of which may be stored in code and/or data storage 605 or code and/or data storage 601 or another storage on or off-chip.

In at least one embodiment, ALU(s) 610 are included within one or more processors or other hardware logic devices or circuits, whereas in another embodiment, ALU(s) 610 may be external to a processor or other hardware logic device or circuit that uses them (e.g., a co-processor). In at least one embodiment, ALUs 610 may be included within a processor's execution units or otherwise within a bank of ALUs accessible by a processor's execution units either within same processor or distributed between different processors of different types (e.g., central processing units, graphics processing units, fixed function units, etc.). In at least one embodiment, code and/or data storage 601, code and/or data storage 605, and activation storage 620 may be on same processor or other hardware logic device or circuit, whereas in another embodiment, they may be in different processors or other hardware logic devices or circuits, or some combination of same and different processors or other hardware logic devices or circuits. In at least one embodiment, any portion of activation storage 620 may be included with other on-chip or off-chip data storage, including a processor's L1, L2, or L3 cache or system memory. Furthermore, inferencing and/or training code may be stored with other code accessible to a processor or other hardware logic or circuit and fetched and/or processed using a processor's fetch, decode, scheduling, execution, retirement and/or other logical circuits.

In at least one embodiment, activation storage 620 may be cache memory, DRAM, SRAM, non-volatile memory (e.g., Flash memory), or other storage. In at least one embodiment, activation storage 620 may be completely or partially within or external to one or more processors or other logical circuits. In at least one embodiment, choice of whether activation storage 620 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors. In at least one embodiment, hardware structure(s) 615 and/or inference and/or training logic illustrated in FIG. 6A may be used in conjunction with an application-specific integrated circuit (“ASIC”), such as Tensorflow® Processing Unit from Google, an inference processing unit (IPU) from Graphcore™, or a Nervana® (e.g., “Lake Crest”) processor from Intel Corp. In at least one embodiment, hardware structure(s) and/or inference and/or training logic of FIG. 6A may be used in conjunction with central processing unit (“CPU”) hardware, graphics processing unit (“GPU”) hardware or other hardware, such as data processing unit (“DPU”) hardware, or field programmable gate arrays (“FPGAs”).

FIG. 6B illustrates hardware structure(s) 615 for inference and/or training logic, according to at least one or more embodiments. In at least one embodiment, hardware structure(s) 615 may include, without limitation, hardware logic in which computational resources are dedicated or otherwise exclusively used in conjunction with weight values or other information corresponding to one or more layers of neurons within a neural network. In at least one embodiment, hardware structure(s) 615 and/or inference and/or training logic of FIG. 6B may be used in conjunction with an application-specific integrated circuit (ASIC), such as Tensorflow® Processing Unit from Google, an inference processing unit (IPU) from Graphcore™, or a Nervana® (e.g., “Lake Crest”) processor from Intel Corp. In at least one embodiment, hardware structure(s) 615 and/or inference and/or training logic of FIG. 6B may be used in conjunction with central processing unit (CPU) hardware, graphics processing unit (GPU) hardware or other hardware, such as data processing unit (“DPU”) hardware, or field programmable gate arrays (FPGAs). In at least one embodiment, inference and/or training logic includes, without limitation, code and/or data storage 601 and code and/or data storage 605, which may be used to store code (e.g., graph code), weight values and/or other information, including bias values, gradient information, momentum values, and/or other parameter or hyperparameter information. In at least one embodiment illustrated in FIG. 6B, each of code and/or data storage 601 and code and/or data storage 605 is associated with a dedicated computational resource, such as computational hardware 602 and computational hardware 606, respectively. In at least one embodiment, each of computational hardware 602 and computational hardware 606 comprises one or more ALUs that perform mathematical functions, such as linear algebraic functions, only on information stored in code and/or data storage 601 and code and/or data storage 605, respectively, result of which is stored in activation storage 620.

In at least one embodiment, each of code and/or data storage 601 and 605 and corresponding computational hardware 602 and 606, respectively, correspond to different layers of a neural network, such that resulting activation from one “storage/computational pair 601/602” of code and/or data storage 601 and computational hardware 602 is provided as an input to “storage/computational pair 605/606” of code and/or data storage 605 and computational hardware 606, in order to mirror conceptual organization of a neural network. In at least one embodiment, each of storage/computational pairs 601/602 and 605/606 may correspond to more than one neural network layer. In at least one embodiment, additional storage/computation pairs (not shown) subsequent to or in parallel with storage computation pairs 601/602 and 605/606 may be included in inference and/or training logic.

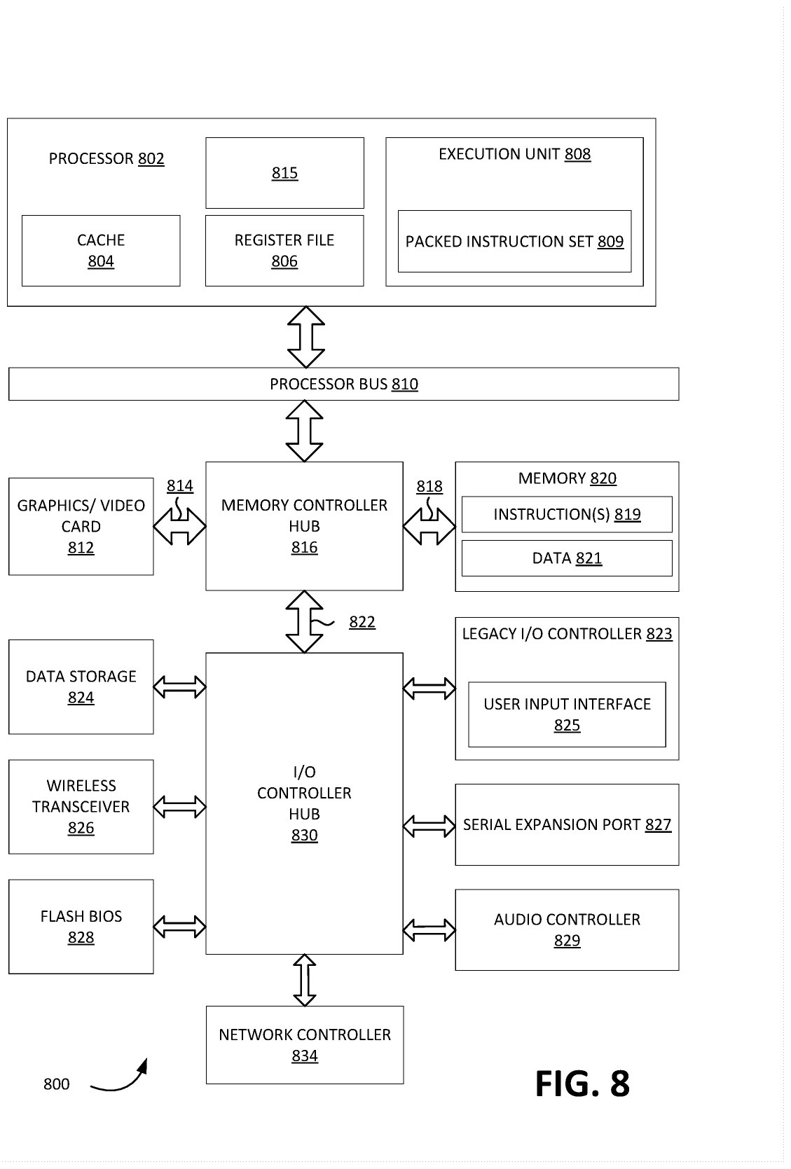

FIG. 7 illustrates an example data center 700, in which at least one embodiment may be used. In at least one embodiment, data center 700 includes a data center infrastructure layer 710, a framework layer 720, a software layer 730, and an application layer 1240.

In at least one embodiment, as shown in FIG. 7, data center infrastructure layer 710 may include a resource orchestrator 712, grouped computing resources 714, and node computing resources (“node C.R.s”) 616(1)-616(N), where “N” represents any whole, positive integer. In at least one embodiment, node C.R.s 616(1)-616(N) may include, but are not limited to, any number of central processing units (“CPUs”) or other processors (including accelerators, field programmable gate arrays (FPGAs), data processing units, graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 616(1)-616(N) may be a server having one or more of above-mentioned computing resources.

In at least one embodiment, grouped computing resources 714 may include separate groupings of node C.R.s housed within one or more racks (not shown), or many racks housed in data centers at various geographical locations (also not shown). Separate groupings of node C.R.s within grouped computing resources 714 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 712 may configure or otherwise control one or more node C.R.s 616(1)-616(N) and/or grouped computing resources 714. In at least one embodiment, resource orchestrator 712 may include a software design infrastructure (“SDI”) management entity for data center 700. In at least one embodiment, resource orchestrator may include hardware, software or some combination thereof.

In at least one embodiment, as shown in FIG. 7, framework layer 720 includes a job scheduler 722, a configuration manager 724, a resource manager 726 and a distributed file system 728. In at least one embodiment, framework layer 720 may include a framework to support software 732 of software layer 730 and/or one or more application(s) 742 of application layer 740. In at least one embodiment, software 732 or application(s) 742 may respectively include web-based service software or applications, such as those provided by Amazon Web Services, Google Cloud and Microsoft Azure. In at least one embodiment, framework layer 720 may be, but is not limited to, a type of free and open-source software web application framework such as Apache Spark™ (hereinafter “Spark”) that may utilize distributed file system 728 for large-scale data processing (e.g., “big data”). In at least one embodiment, job scheduler 722 may include a Spark driver to facilitate scheduling of workloads supported by various layers of data center 700. In at least one embodiment, configuration manager 724 may be capable of configuring different layers such as software layer 730 and framework layer 720 including Spark and distributed file system 728 for supporting large-scale data processing. In at least one embodiment, resource manager 726 may be capable of managing clustered or grouped computing resources mapped to or allocated for support of distributed file system 728 and job scheduler 722. In at least one embodiment, clustered or grouped computing resources may include grouped computing resource 714 at data center infrastructure layer 710. In at least one embodiment, resource manager 726 may coordinate with resource orchestrator 712 to manage these mapped or allocated computing resources.

In at least one embodiment, software 732 included in software layer 730 may include software used by at least portions of node C.R.s 616(1)-616(N), grouped computing resources 714, and/or distributed file system 728 of framework layer 720. The one or more types of software may include, but are not limited to, Internet web page search software, e-mail virus scan software, database software, and streaming video content software.

In at least one embodiment, application(s) 742 included in application layer 740 may include one or more types of applications used by at least portions of node C.R.s 616(1)-616(N), grouped computing resources 714, and/or distributed file system 728 of framework layer 720. One or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 724, resource manager 726, and resource orchestrator 712 may implement any number and type of self-modifying actions based on any amount and type of data acquired in any technically feasible fashion. In at least one embodiment, self-modifying actions may relieve a data center operator of data center 700 from making possibly bad configuration decisions and possibly avoiding underutilized and/or poor performing portions of a data center.

In at least one embodiment, data center 700 may include tools, services, software, or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 700. In at least one embodiment, trained machine learning models corresponding to one or more neural networks may be used to infer or predict information using resources described above with respect to data center 700 by using weight parameters calculated through one or more training techniques described herein.

In at least one embodiment, data center may use CPUs, application-specific integrated circuits (ASICs), GPUs, DPUs FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic are used to perform inferencing and/or training operations associated with one or more embodiments. Details regarding inference and/or training logic are provided in conjunction with FIGS. 6A and/or 6B. In at least one embodiment, inference and/or training logic may be used in system FIG. 7 for inferencing or predicting operations based, at least in part, on weight parameters calculated using neural network training operations, neural network functions and/or architectures, or neural network use cases described herein.

Such components may be used to generate synthetic data imitating failure cases in a network training process, which may help to improve performance of the network while limiting the amount of synthetic data to avoid overfitting.

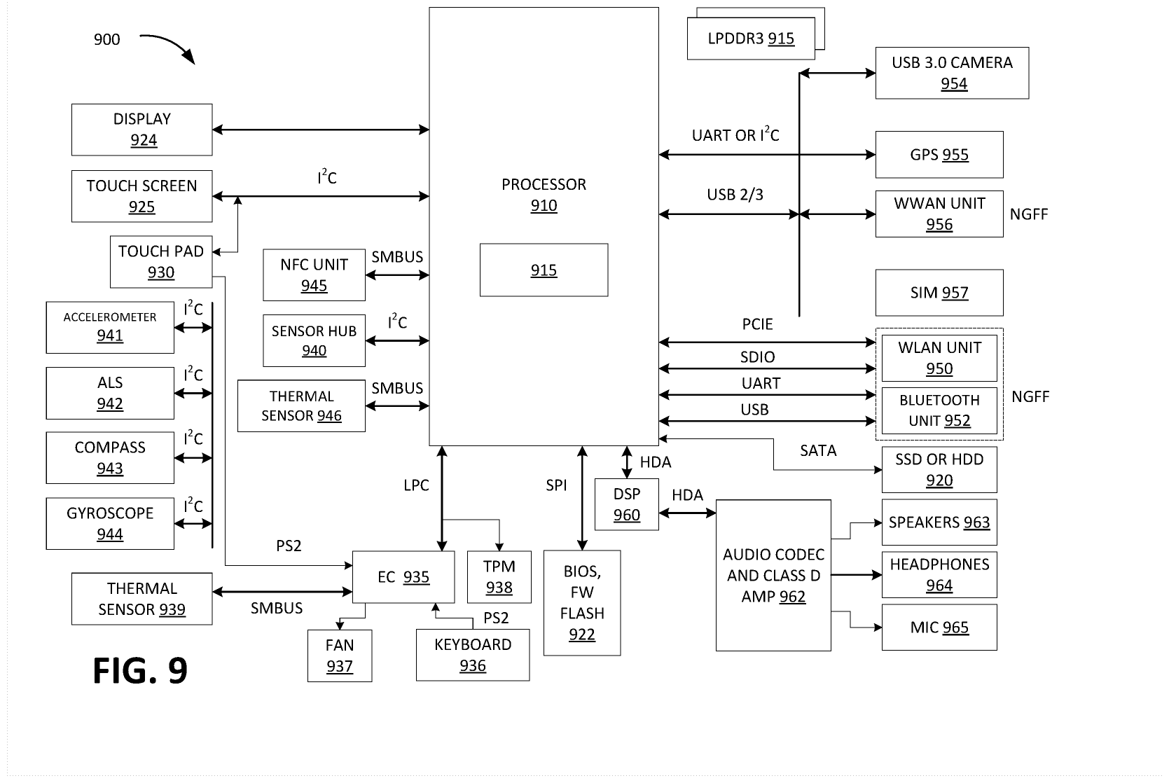

FIG. 8 is a block diagram illustrating an exemplary computer system, which may be a system with interconnected devices and components, a system-on-a-chip (SOC) or some combination thereof 800 formed with a processor that may include execution units to execute an instruction, according to at least one embodiment. In at least one embodiment, computer system 800 may include, without limitation, a component, such as a processor 802 to employ execution units including logic to perform algorithms for process data, in accordance with present disclosure, such as in embodiment described herein. In at least one embodiment, computer system 800 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 800 may execute a version of WINDOWS' operating system available from Microsoft Corporation of Redmond, Wash., although other operating systems (UNIX and Linux for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“NetPCs”), set-top boxes, network hubs, wide area network (“WAN”) switches, edge devices, Internet-of-Things (“IoT”) devices, or any other system that may perform one or more instructions in accordance with at least one embodiment.

In at least one embodiment, computer system 800 may include, without limitation, processor 802 that may include, without limitation, one or more execution units 808 to perform machine learning model training and/or inferencing according to techniques described herein. In at least one embodiment, computer system 800 is a single processor desktop or server system, but in another embodiment computer system 800 may be a multiprocessor system. In at least one embodiment, processor 802 may include, without limitation, a complex instruction set computer (“CISC”) microprocessor, a reduced instruction set computing (“RISC”) microprocessor, a very long instruction word (“VLIW”) microprocessor, a processor implementing a combination of instruction sets, or any other processor device, such as a digital signal processor, for example. In at least one embodiment, processor 802 may be coupled to a processor bus 810 that may transmit data signals between processor 802 and other components in computer system 800.

In at least one embodiment, processor 802 may include, without limitation, a Level 1 (“L1”) internal cache memory (“cache”) 804. In at least one embodiment, processor 802 may have a single internal cache or multiple levels of internal cache. In at least one embodiment, cache memory may reside external to processor 802. Other embodiments may also include a combination of both internal and external caches depending on particular implementation and needs. In at least one embodiment, register file 806 may store different types of data in various registers including, without limitation, integer registers, floating point registers, status registers, and instruction pointer register.

In at least one embodiment, execution unit 808, including, without limitation, logic to perform integer and floating point operations, also resides in processor 802. In at least one embodiment, processor 802 may also include a microcode (“ucode”) read only memory (“ROM”) that stores microcode for certain macro instructions. In at least one embodiment, execution unit 808 may include logic to handle a packed instruction set 809. In at least one embodiment, by including packed instruction set 809 in an instruction set of a general-purpose processor 802, along with associated circuitry to execute instructions, operations used by many multimedia applications may be performed using packed data in a general-purpose processor 802. In one or more embodiments, many multimedia applications may be accelerated and executed more efficiently by using full width of a processor's data bus for performing operations on packed data, which may eliminate need to transfer smaller units of data across processor's data bus to perform one or more operations one data element at a time.

In at least one embodiment, execution unit 808 may also be used in microcontrollers, embedded processors, graphics devices, DSPs, and other types of logic circuits. In at least one embodiment, computer system 800 may include, without limitation, a memory 820. In at least one embodiment, memory 820 may be implemented as a Dynamic Random Access Memory (“DRAM”) device, a Static Random Access Memory (“SRAM”) device, flash memory device, or other memory device. In at least one embodiment, memory 820 may store instruction(s) 819 and/or data 821 represented by data signals that may be executed by processor 802.

In at least one embodiment, system logic chip may be coupled to processor bus 810 and memory 820. In at least one embodiment, system logic chip may include, without limitation, a memory controller hub (“MCH”) 816, and processor 802 may communicate with MCH 816 via processor bus 810. In at least one embodiment, MCH 816 may provide a high bandwidth memory path 818 to memory 820 for instruction and data storage and for storage of graphics commands, data and textures. In at least one embodiment, MCH 816 may direct data signals between processor 802, memory 820, and other components in computer system 800 and to bridge data signals between processor bus 810, memory 820, and a system I/O 822. In at least one embodiment, system logic chip may provide a graphics port for coupling to a graphics controller. In at least one embodiment, MCH 816 may be coupled to memory 820 through a high bandwidth memory path 818 and graphics/video card 812 may be coupled to MCH 816 through an Accelerated Graphics Port (“AGP”) interconnect 814.

In at least one embodiment, computer system 800 may use system I/O 822 that is a proprietary hub interface bus to couple MCH 816 to I/O controller hub (“ICH”) 830. In at least one embodiment, ICH 830 may provide direct connections to some I/O devices via a local I/O bus. In at least one embodiment, local I/O bus may include, without limitation, a high-speed I/O bus for connecting peripherals to memory 820, chipset, and processor 802. Examples may include, without limitation, an audio controller 829, a firmware hub (“flash BIOS”) 828, a wireless transceiver 826, a data storage 824, a legacy I/O controller 823 containing user input and keyboard interfaces 825, a serial expansion port 827, such as Universal Serial Bus (“USB”), and a network controller 834, which may include in some embodiments, a data processing unit. Data storage 824 may comprise a hard disk drive, a floppy disk drive, a CD-ROM device, a flash memory device, or other mass storage device.

In at least one embodiment, FIG. 8 illustrates a system, which includes interconnected hardware devices or “chips,” whereas in other embodiments, FIG. 8 may illustrate an exemplary System on a Chip (“SoC”). In at least one embodiment, devices may be interconnected with proprietary interconnects, standardized interconnects (e.g., PCIe) or some combination thereof. In at least one embodiment, one or more components of computer system 800 are interconnected using compute express link (CXL) interconnects.

Inference and/or training logic 615 are used to perform inferencing and/or training operations associated with one or more embodiments. Details regarding inference and/or training logic 615 are provided below in conjunction with FIGS. 6A and/or 6B. In at least one embodiment, inference and/or training logic 615 may be used in system FIG. 8 for inferencing or predicting operations based, at least in part, on weight parameters calculated using neural network training operations, neural network functions and/or architectures, or neural network use cases described herein.

Such components may be used to generate synthetic data imitating failure cases in a network training process, which may help to improve performance of the network while limiting the amount of synthetic data to avoid overfitting.

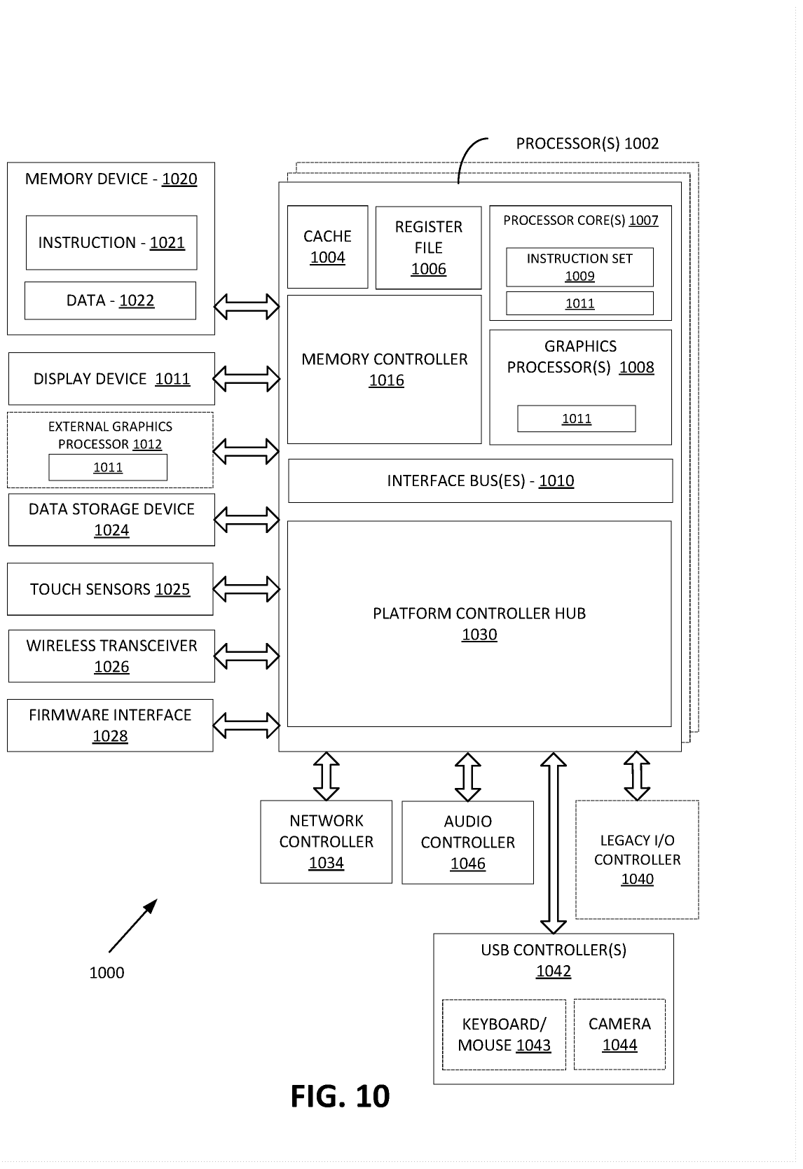

FIG. 9 is a block diagram illustrating an electronic device 900 for utilizing a processor 910, according to at least one embodiment. In at least one embodiment, electronic device 900 may be, for example and without limitation, a notebook, a tower server, a rack server, a blade server, a laptop, a desktop, a tablet, a mobile device, a phone, an embedded computer, an edge device, an IoT device, or any other suitable electronic device.

In at least one embodiment, system 900 may include, without limitation, processor 910 communicatively coupled to any suitable number or kind of components, peripherals, modules, or devices. In at least one embodiment, processor 910 coupled using a bus or interface, such as a 1° C. bus, a System Management Bus (“SMBus”), a Low Pin Count (LPC) bus, a Serial Peripheral Interface (“SPI”), a High Definition Audio (“HDA”) bus, a Serial Advance Technology Attachment (“SATA”) bus, a Universal Serial Bus (“USB”) (versions 1, 2, 3), or a Universal Asynchronous Receiver/Transmitter (“UART”) bus. In at least one embodiment, FIG. 9 illustrates a system, which includes interconnected hardware devices or “chips,” whereas in other embodiments, FIG. 9 may illustrate an exemplary System on a Chip (“SoC”). In at least one embodiment, devices illustrated in FIG. 9 may be interconnected with proprietary interconnects, standardized interconnects (e.g., PCIe) or some combination thereof. In at least one embodiment, one or more components of FIG. 9 are interconnected using compute express link (CXL) interconnects.

In at least one embodiment, FIG. 9 may include a display 924, a touch screen 925, a touch pad 930, a Near Field Communications unit (“NFC”) 945, a sensor hub 940, a thermal sensor 946, an Express Chipset (“EC”) 935, a Trusted Platform Module (“TPM”) 938, BIOS/firmware/flash memory (“BIOS, FW Flash”) 922, a DSP 960, a drive 920 such as a Solid State Disk (“SSD”) or a Hard Disk Drive (“HDD”), a wireless local area network unit (“WLAN”) 950, a Bluetooth unit 952, a Wireless Wide Area Network unit (“WWAN”) 956, a Global Positioning System (GPS) 955, a camera (“USB 3.0 camera”) 954 such as a USB 3.0 camera, and/or a Low Power Double Data Rate (“LPDDR”) memory unit (“LPDDR3”) 915 implemented in, for example, LPDDR3 standard. These components may each be implemented in any suitable manner.

In at least one embodiment, other components may be communicatively coupled to processor 910 through components discussed above. In at least one embodiment, an accelerometer 941, Ambient Light Sensor (“ALS”) 942, compass 943, and a gyroscope 944 may be communicatively coupled to sensor hub 940. In at least one embodiment, thermal sensor 939, a fan 937, a keyboard 936, and a touch pad 930 may be communicatively coupled to EC 935. In at least one embodiment, speaker 963, headphones 964, and microphone (“mic”) 965 may be communicatively coupled to an audio unit (“audio codec and class d amp”) 962, which may in turn be communicatively coupled to DSP 960. In at least one embodiment, audio unit 964 may include, for example and without limitation, an audio coder/decoder (“codec”) and a class D amplifier. In at least one embodiment, SIM card (“SIM”) 957 may be communicatively coupled to WWAN unit 956. In at least one embodiment, components such as WLAN unit 950 and Bluetooth unit 952, as well as WWAN unit 956 may be implemented in a Next Generation Form Factor (“NGFF”).

Inference and/or training logic 615 are used to perform inferencing and/or training operations associated with one or more embodiments. Details regarding inference and/or training logic 615 are provided below in conjunction with FIGS. 6A and/or 6B. In at least one embodiment, inference and/or training logic 615 may be used in system FIG. 9 for inferencing or predicting operations based, at least in part, on weight parameters calculated using neural network training operations, neural network functions and/or architectures, or neural network use cases described herein.

Such components may be used to generate synthetic data imitating failure cases in a network training process, which may help to improve performance of the network while limiting the amount of synthetic data to avoid overfitting.

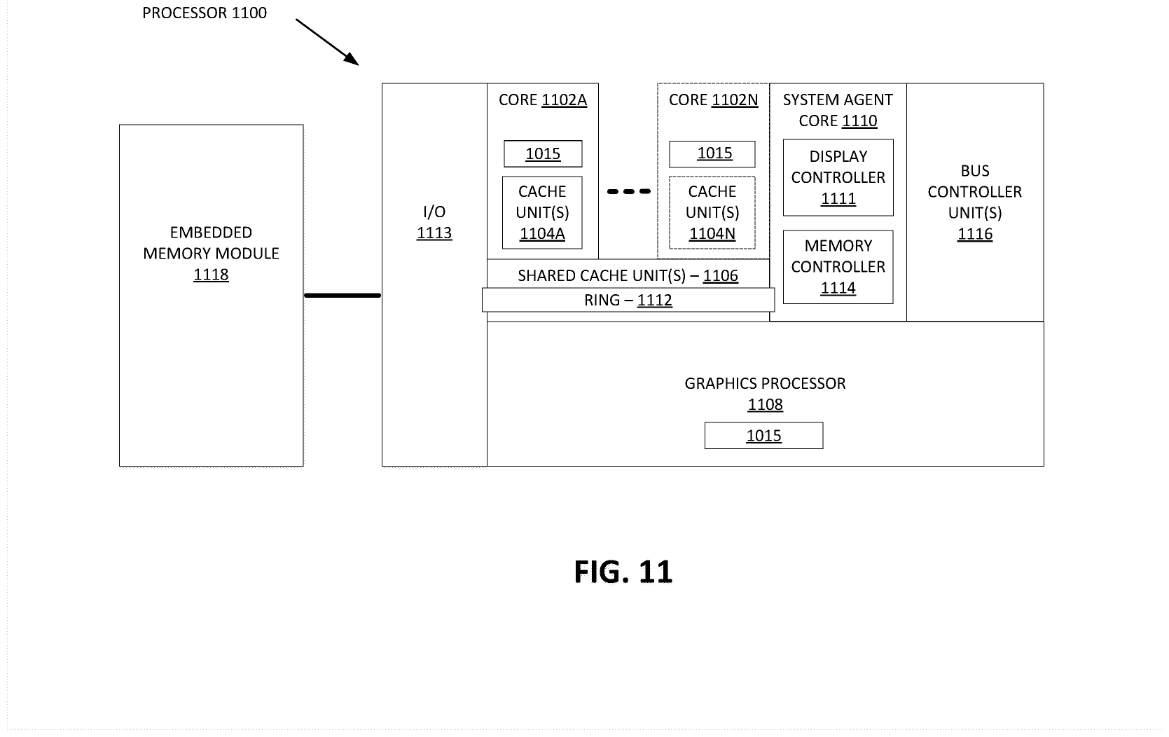

FIG. 10 is a block diagram of a processing system, according to at least one embodiment. In at least one embodiment, system 1000 includes one or more processors 1002 and one or more graphics processors 1008, and may be a single processor desktop system, a multiprocessor workstation system, or a server system having a large number of processors 1002 or processor cores 1007. In at least one embodiment, system 1000 is a processing platform incorporated within a system-on-a-chip (SoC) integrated circuit for use in mobile, handheld, edge, or embedded devices.

In at least one embodiment, system 1000 may include, or be incorporated within a server-based gaming platform, a game console, including a game and media console, a mobile gaming console, a handheld game console, or an online game console. In at least one embodiment, system 1000 is a mobile phone, smart phone, tablet computing device or mobile Internet device. In at least one embodiment, processing system 1000 may also include, couple with, or be integrated within a wearable device, such as a smart watch wearable device, smart eyewear device, augmented reality device, or virtual reality device. In at least one embodiment, processing system 1000 is a television or set top box device having one or more processors 1002 and a graphical interface generated by one or more graphics processors 1008.

In at least one embodiment, one or more processors 1002 each include one or more processor cores 1007 to process instructions which, when executed, perform operations for system and user software. In at least one embodiment, each of one or more processor cores 1007 is configured to process a specific instruction set 1009. In at least one embodiment, instruction set 1009 may facilitate Complex Instruction Set Computing (CISC), Reduced Instruction Set Computing (RISC), or computing via a Very Long Instruction Word (VLIW). In at least one embodiment, processor cores 1007 may each process a different instruction set 1009, which may include instructions to facilitate emulation of other instruction sets. In at least one embodiment, processor core 1007 may also include other processing devices, such a Digital Signal Processor (DSP).

In at least one embodiment, processor 1002 includes cache memory 1004. In at least one embodiment, processor 1002 may have a single internal cache or multiple levels of internal cache. In at least one embodiment, cache memory is shared among various components of processor 1002. In at least one embodiment, processor 1002 also uses an external cache (e.g., a Level-3 (L3) cache or Last Level Cache (LLC)) (not shown), which may be shared among processor cores 1007 using known cache coherency techniques. In at least one embodiment, register file 1006 is additionally included in processor 1002 which may include different types of registers for storing different types of data (e.g., integer registers, floating point registers, status registers, and an instruction pointer register). In at least one embodiment, register file 1006 may include general-purpose registers or other registers.

In at least one embodiment, one or more processor(s) 1002 are coupled with one or more interface bus(es) 1010 to transmit communication signals such as address, data, or control signals between processor 1002 and other components in system 1000. In at least one embodiment, interface bus 1010, in one embodiment, may be a processor bus, such as a version of a Direct Media Interface (DMI) bus. In at least one embodiment, interface 1010 is not limited to a DMI bus, and may include one or more Peripheral Component Interconnect buses (e.g., PCI, PCI Express), memory busses, or other types of interface busses. In at least one embodiment processor(s) 1002 include an integrated memory controller 1016 and a platform controller hub 1030. In at least one embodiment, memory controller 1016 facilitates communication between a memory device and other components of system 1000, while platform controller hub (PCH) 1030 provides connections to I/O devices via a local I/O bus.

In at least one embodiment, memory device 1020 may be a dynamic random access memory (DRAM) device, a static random access memory (SRAM) device, flash memory device, phase-change memory device, or some other memory device having suitable performance to serve as process memory. In at least one embodiment memory device 1020 may operate as system memory for system 1000, to store data 1022 and instructions 1021 for use when one or more processors 1002 executes an application or process. In at least one embodiment, memory controller 1016 also couples with an optional external graphics processor 1012, which may communicate with one or more graphics processors 1008 in processors 1002 to perform graphics and media operations. In at least one embodiment, a display device 1011 may connect to processor(s) 1002. In at least one embodiment display device 1011 may include one or more of an internal display device, as in a mobile electronic device or a laptop device or an external display device attached via a display interface (e.g., DisplayPort, etc.). In at least one embodiment, display device 1011 may include a head mounted display (HMD) such as a stereoscopic display device for use in virtual reality (VR) applications or augmented reality (AR) applications.

In at least one embodiment, platform controller hub 1030 enables peripherals to connect to memory device 1020 and processor 1002 via a high-speed I/O bus. In at least one embodiment, I/O peripherals include, but are not limited to, an audio controller 1046, a network controller 1034, a firmware interface 1028, a wireless transceiver 1026, touch sensors 1025, a data storage device 1024 (e.g., hard disk drive, flash memory, etc.). In at least one embodiment, data storage device 1024 may connect via a storage interface (e.g., SATA) or via a peripheral bus, such as a Peripheral Component Interconnect bus (e.g., PCI, PCI Express). In at least one embodiment, touch sensors 1025 may include touch screen sensors, pressure sensors, or fingerprint sensors. In at least one embodiment, wireless transceiver 1026 may be a Wi-Fi transceiver, a Bluetooth transceiver, or a mobile network transceiver such as a 3G, 4G, or Long Term Evolution (LTE) transceiver. In at least one embodiment, firmware interface 1028 enables communication with system firmware, and may be, for example, a unified extensible firmware interface (UEFI). In at least one embodiment, network controller 1034 may enable a network connection to a wired network. In at least one embodiment, a high-performance network controller (not shown) couples with interface bus 1010. In at least one embodiment, audio controller 1046 is a multi-channel high definition audio controller. In at least one embodiment, system 1000 includes an optional legacy I/O controller 1040 for coupling legacy (e.g., Personal System 2 (PS/2)) devices to system. In at least one embodiment, platform controller hub 1030 may also connect to one or more Universal Serial Bus (USB) controllers 1042 connect input devices, such as keyboard and mouse 1043 combinations, a camera 1044, or other USB input devices.

In at least one embodiment, an instance of memory controller 1016 and platform controller hub 1030 may be integrated into a discreet external graphics processor, such as external graphics processor 1011. In at least one embodiment, platform controller hub 1030 and/or memory controller 1016 may be external to one or more processor(s) 1002. For example, in at least one embodiment, system 1000 may include an external memory controller 1016 and platform controller hub 1030, which may be configured as a memory controller hub and peripheral controller hub within a system chipset that is in communication with processor(s) 1002.

Inference and/or training logic 615 are used to perform inferencing and/or training operations associated with one or more embodiments. Details regarding inference and/or training logic 615 are provided below in conjunction with FIGS. 6A and/or 6B. In at least one embodiment portions or all of inference and/or training logic 615 may be incorporated into graphics processor 1008. For example, in at least one embodiment, training and/or inferencing techniques described herein may use one or more of ALUs embodied in a graphics processor. Moreover, in at least one embodiment, inferencing and/or training operations described herein may be done using logic other than logic illustrated in FIG. 6A or 6B. In at least one embodiment, weight parameters may be stored in on-chip or off-chip memory and/or registers (shown or not shown) that configure ALUs of a graphics processor to perform one or more machine learning algorithms, neural network architectures, use cases, or training techniques described herein.

Such components may be used to generate synthetic data imitating failure cases in a network training process, which may help to improve performance of the network while limiting the amount of synthetic data to avoid overfitting.

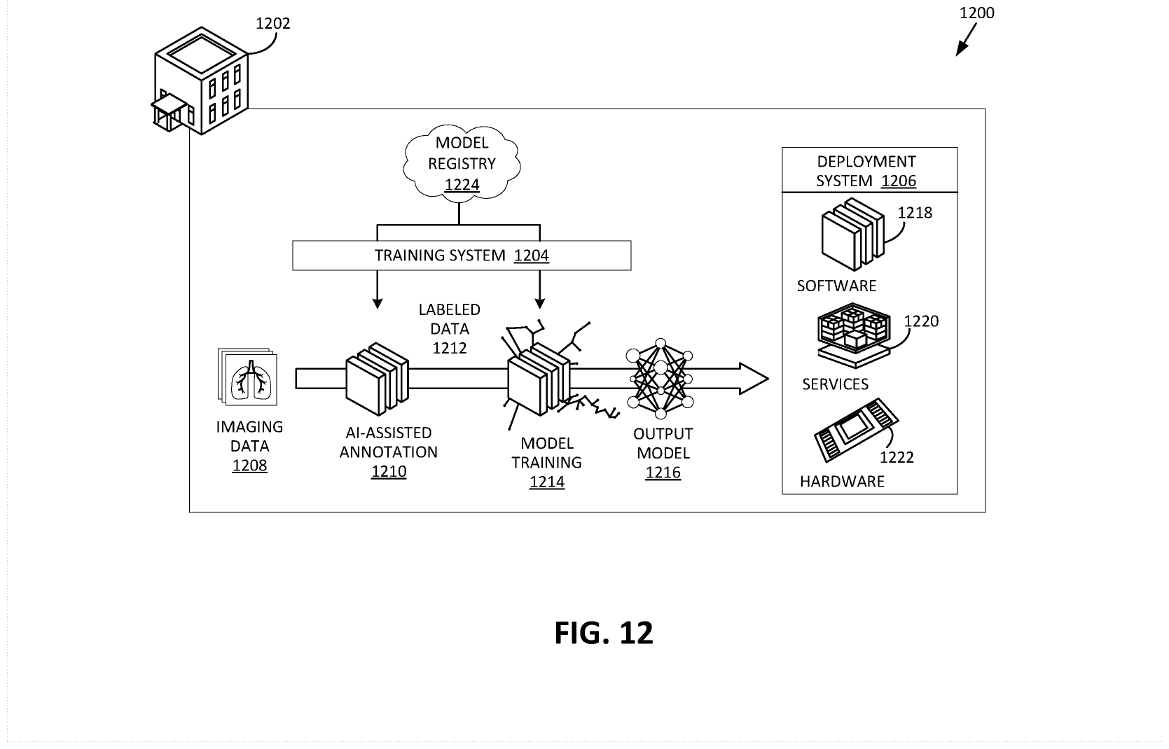

FIG. 11 is a block diagram of a processor 1100 having one or more processor cores 1102A-1102N, an integrated memory controller 1113, and an integrated graphics processor 1108, according to at least one embodiment. In at least one embodiment, processor 1100 may include additional cores up to and including additional core 1102N represented by dashed lined boxes. In at least one embodiment, each of processor cores 1102A-1102N includes one or more internal cache units 1104A-1104N. In at least one embodiment, each processor core also has access to one or more shared cached units 1106.

In at least one embodiment, internal cache units 1104A-1104N and shared cache units 1106 represent a cache memory hierarchy within processor 1100. In at least one embodiment, cache memory units 1104A-1104N may include at least one level of instruction and data cache within each processor core and one or more levels of shared mid-level cache, such as a Level 2 (L2), Level 3 (L3), Level 4 (L4), or other levels of cache, where a highest level of cache before external memory is classified as an LLC. In at least one embodiment, cache coherency logic maintains coherency between various cache units 1106 and 1104A-1104N.

In at least one embodiment, processor 1100 may also include a set of one or more bus controller units 1116 and a system agent core 1110. In at least one embodiment, one or more bus controller units 1116 manage a set of peripheral buses, such as one or more PCI or PCI express busses. In at least one embodiment, system agent core 1110 provides management functionality for various processor components. In at least one embodiment, system agent core 1110 includes one or more integrated memory controllers 1113 to manage access to various external memory devices (not shown).

In at least one embodiment, one or more of processor cores 1102A-1102N include support for simultaneous multi-threading. In at least one embodiment, system agent core 1110 includes components for coordinating and operating cores 1102A-1102N during multi-threaded processing. In at least one embodiment, system agent core 1110 may additionally include a power control unit (PCU), which includes logic and components to regulate one or more power states of processor cores 1102A-1102N and graphics processor 1108.

In at least one embodiment, processor 1100 additionally includes graphics processor 1108 to execute graphics processing operations. In at least one embodiment, graphics processor 1108 couples with shared cache units 1106, and system agent core 1110, including one or more integrated memory controllers 1113. In at least one embodiment, system agent core 1110 also includes a display controller 1111 to drive graphics processor output to one or more coupled displays. In at least one embodiment, display controller 1111 may also be a separate module coupled with graphics processor 1108 via at least one interconnect, or may be integrated within graphics processor 1108.

In at least one embodiment, a ring based interconnect unit 1112 is used to couple internal components of processor 1100. In at least one embodiment, an alternative interconnect unit may be used, such as a point-to-point interconnect, a switched interconnect, or other techniques. In at least one embodiment, graphics processor 1108 couples with ring interconnect 1112 via an I/O link 1113.

In at least one embodiment, I/O link 1113 represents at least one of multiple varieties of I/O interconnects, including an on package I/O interconnect which facilitates communication between various processor components and a high-performance embedded memory module 1118, such as an eDRAM module. In at least one embodiment, each of processor cores 1102A-1102N and graphics processor 1108 use embedded memory modules 1118 as a shared Last Level Cache.

In at least one embodiment, processor cores 1102A-1102N are homogenous cores executing a common instruction set architecture. In at least one embodiment, processor cores 1102A-1102N are heterogeneous in terms of instruction set architecture (ISA), where one or more of processor cores 1102A-1102N execute a common instruction set, while one or more other cores of processor cores 1102A-1102N executes a subset of a common instruction set or a different instruction set. In at least one embodiment, processor cores 1102A-1102N are heterogeneous in terms of microarchitecture, where one or more cores having a relatively higher power consumption couple with one or more power cores having a lower power consumption. In at least one embodiment, processor 1100 may be implemented on one or more chips or as a SoC integrated circuit.

Inference and/or training logic 615 are used to perform inferencing and/or training operations associated with one or more embodiments. Details regarding inference and/or training logic 615 are provided below in conjunction with FIGS. 6A and/or 6B. In at least one embodiment portions or all of inference and/or training logic 615 may be incorporated into processor 1100. For example, in at least one embodiment, training and/or inferencing techniques described herein may use one or more of ALUs embodied in graphics processor 1108, graphics core(s) 1102A-1102N, or other components in FIG. 11. Moreover, in at least one embodiment, inferencing and/or training operations described herein may be done using logic other than logic illustrated in FIG. 6A or 6B. In at least one embodiment, weight parameters may be stored in on-chip or off-chip memory and/or registers (shown or not shown) that configure ALUs of graphics processor 1100 to perform one or more machine learning algorithms, neural network architectures, use cases, or training techniques described herein.

Such components may be used to generate synthetic data imitating failure cases in a network training process, which may help to improve performance of the network while limiting the amount of synthetic data to avoid overfitting.

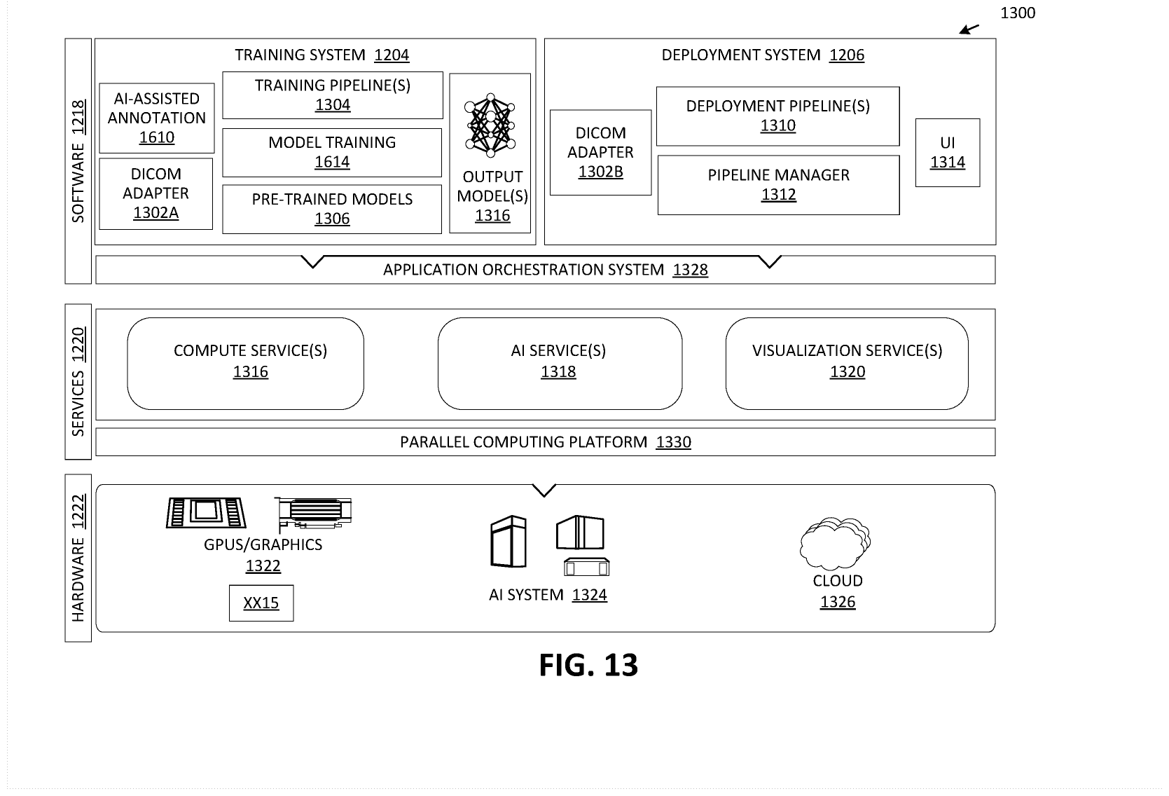

FIG. 12 is an example data flow diagram for a process 1200 of generating and deploying an image processing and inferencing pipeline, in accordance with at least one embodiment. In at least one embodiment, process 1200 may be deployed for use with imaging devices, processing devices, and/or other device types at one or more facilities 1202. Process 1200 may be executed within a training system 1204 and/or a deployment system 1206. In at least one embodiment, training system 1204 may be used to perform training, deployment, and implementation of machine learning models (e.g., neural networks, object detection algorithms, computer vision algorithms, etc.) for use in deployment system 1206. In at least one embodiment, deployment system 1206 may be configured to offload processing and compute resources among a distributed computing environment to reduce infrastructure requirements at facility 1202. In at least one embodiment, one or more applications in a pipeline may use or call upon services (e.g., inference, visualization, compute, AI, etc.) of deployment system 1206 during execution of applications.

In at least one embodiment, some of applications used in advanced processing and inferencing pipelines may use machine learning models or other AI to perform one or more processing steps. In at least one embodiment, machine learning models may be trained at facility 1202 using data 1208 (such as imaging data) generated at facility 1202 (and stored on one or more picture archiving and communication system (PACS) servers at facility 1202), may be trained using imaging or sequencing data 1208 from another facility (ies), or a combination thereof. In at least one embodiment, training system 1204 may be used to provide applications, services, and/or other resources for generating working, deployable machine learning models for deployment system 1206.

In at least one embodiment, model registry 1224 may be backed by object storage that may support versioning and object metadata. In at least one embodiment, object storage may be accessible through, for example, a cloud storage (e.g., cloud 1226 of FIG. 12) compatible application programming interface (API) from within a cloud platform. In at least one embodiment, machine learning models within model registry 1224 may uploaded, listed, modified, or deleted by developers or partners of a system interacting with an API. In at least one embodiment, an API may provide access to methods that allow users with appropriate credentials to associate models with applications, such that models may be executed as part of execution of containerized instantiations of applications.

In at least one embodiment, training pipeline 1204 (FIG. 12) may include a scenario where facility 1202 is training their own machine learning model, or has an existing machine learning model that needs to be optimized or updated. In at least one embodiment, imaging data 1208 generated by imaging device(s), sequencing devices, and/or other device types may be received. In at least one embodiment, once imaging data 1208 is received, AI-assisted annotation 1210 may be used to aid in generating annotations corresponding to imaging data 1208 to be used as ground truth data for a machine learning model. In at least one embodiment, AI-assisted annotation 1210 may include one or more machine learning models (e.g., convolutional neural networks (CNNs)) that may be trained to generate annotations corresponding to certain types of imaging data 1208 (e.g., from certain devices). In at least one embodiment, AI-assisted annotations 1210 may then be used directly, or may be adjusted or fine-tuned using an annotation tool to generate ground truth data. In at least one embodiment, AI-assisted annotations 1210, labeled clinic data 1212, or a combination thereof may be used as ground truth data for training a machine learning model. In at least one embodiment, a trained machine learning model may be referred to as output model 1216, and may be used by deployment system 1206, as described herein.

In at least one embodiment, training pipeline 1204 (FIG. 12) may include a scenario where facility 1202 needs a machine learning model for use in performing one or more processing tasks for one or more applications in deployment system 1206, but facility 1202 may not currently have such a machine learning model (or may not have a model that is optimized, efficient, or effective for such purposes). In at least one embodiment, an existing machine learning model may be selected from a model registry 1224. In at least one embodiment, model registry 1224 may include machine learning models trained to perform a variety of different inference tasks on imaging data. In at least one embodiment, machine learning models in model registry 1224 may have been trained on imaging data from different facilities than facility 1202 (e.g., facilities remotely located). In at least one embodiment, machine learning models may have been trained on imaging data from one location, two locations, or any number of locations. In at least one embodiment, when being trained on imaging data from a specific location, training may take place at that location, or at least in a manner that protects confidentiality of imaging data or restricts imaging data from being transferred off-premises. In at least one embodiment, once a model is trained—or partially trained—at one location, a machine learning model may be added to model registry 1224. In at least one embodiment, a machine learning model may then be retrained, or updated, at any number of other facilities, and a retrained or updated model may be made available in model registry 1224. In at least one embodiment, a machine learning model may then be selected from model registry 1224—and referred to as output model 1216—and may be used in deployment system 1206 to perform one or more processing tasks for one or more applications of a deployment system.

In at least one embodiment, training pipeline 1204 (FIG. 12), a scenario may include facility 1202 requiring a machine learning model for use in performing one or more processing tasks for one or more applications in deployment system 1206, but facility 1202 may not currently have such a machine learning model (or may not have a model that is optimized, efficient, or effective for such purposes). In at least one embodiment, a machine learning model selected from model registry 1224 may not be fine-tuned or optimized for imaging data 1208 generated at facility 1202 because of differences in populations, robustness of training data used to train a machine learning model, diversity in anomalies of training data, and/or other issues with training data. In at least one embodiment, AI-assisted annotation 1210 may be used to aid in generating annotations corresponding to imaging data 1208 to be used as ground truth data for retraining or updating a machine learning model. In at least one embodiment, labeled data 1212 may be used as ground truth data for training a machine learning model. In at least one embodiment, retraining or updating a machine learning model may be referred to as model training 1214. In at least one embodiment, model training 1214—e.g., AI-assisted annotations 1210, labeled clinic data 1212, or a combination thereof—may be used as ground truth data for retraining or updating a machine learning model. In at least one embodiment, a trained machine learning model may be referred to as output model 1216, and may be used by deployment system 1206, as described herein.

In at least one embodiment, deployment system 1206 may include software 1218, services 1220, hardware 1222, and/or other components, features, and functionality. In at least one embodiment, deployment system 1206 may include a software “stack,” such that software 1218 may be built on top of services 1220 and may use services 1220 to perform some or all of processing tasks, and services 1220 and software 1218 may be built on top of hardware 1222 and use hardware 1222 to execute processing, storage, and/or other compute tasks of deployment system 1206. In at least one embodiment, software 1218 may include any number of different containers, where each container may execute an instantiation of an application. In at least one embodiment, each application may perform one or more processing tasks in an advanced processing and inferencing pipeline (e.g., inferencing, object detection, feature detection, segmentation, image enhancement, calibration, etc.). In at least one embodiment, an advanced processing and inferencing pipeline may be defined based on selections of different containers that are desired or required for processing imaging data 1208, in addition to containers that receive and configure imaging data for use by each container and/or for use by facility 1202 after processing through a pipeline (e.g., to convert outputs back to a usable data type). In at least one embodiment, a combination of containers within software 1218 (e.g., that make up a pipeline) may be referred to as a virtual instrument (as described in more detail herein), and a virtual instrument may leverage services 1220 and hardware 1222 to execute some or all processing tasks of applications instantiated in containers.

In at least one embodiment, a data processing pipeline may receive input data (e.g., imaging data 1208) in a specific format in response to an inference request (e.g., a request from a user of deployment system 1206). In at least one embodiment, input data may be representative of one or more images, video, and/or other data representations generated by one or more imaging devices. In at least one embodiment, data may undergo pre-processing as part of data processing pipeline to prepare data for processing by one or more applications. In at least one embodiment, post-processing may be performed on an output of one or more inferencing tasks or other processing tasks of a pipeline to prepare an output data for a next application and/or to prepare output data for transmission and/or use by a user (e.g., as a response to an inference request). In at least one embodiment, inferencing tasks may be performed by one or more machine learning models, such as trained or deployed neural networks, which may include output models 1216 of training system 1204.

In at least one embodiment, tasks of data processing pipeline may be encapsulated in a container(s) that each represents a discrete, fully functional instantiation of an application and virtualized computing environment that is able to reference machine learning models. In at least one embodiment, containers or applications may be published into a private (e.g., limited access) area of a container registry (described in more detail herein), and trained or deployed models may be stored in model registry 1224 and associated with one or more applications. In at least one embodiment, images of applications (e.g., container images) may be available in a container registry, and once selected by a user from a container registry for deployment in a pipeline, an image may be used to generate a container for an instantiation of an application for use by a user's system.

In at least one embodiment, developers (e.g., software developers, clinicians, doctors, etc.) may develop, publish, and store applications (e.g., as containers) for performing image processing and/or inferencing on supplied data. In at least one embodiment, development, publishing, and/or storing may be performed using a software development kit (SDK) associated with a system (e.g., to ensure that an application and/or container developed is compliant with or compatible with a system). In at least one embodiment, an application that is developed may be tested locally (e.g., at a first facility, on data from a first facility) with an SDK which may support at least some of services 1220 as a system (e.g., system 1200 of FIG. 12). In at least one embodiment, because DICOM objects may contain anywhere from one to hundreds of images or other data types, and due to a variation in data, a developer may be responsible for managing (e.g., setting constructs for, building pre-processing into an application, etc.) extraction and preparation of incoming data. In at least one embodiment, once validated by system 1200 (e.g., for accuracy), an application may be available in a container registry for selection and/or implementation by a user to perform one or more processing tasks with respect to data at a facility (e.g., a second facility) of a user.

In at least one embodiment, developers may then share applications or containers through a network for access and use by users of a system (e.g., system 1200 of FIG. 12). In at least one embodiment, completed and validated applications or containers may be stored in a container registry and associated machine learning models may be stored in model registry 1224. In at least one embodiment, a requesting entity-who provides an inference or image processing request—may browse a container registry and/or model registry 1224 for an application, container, dataset, machine learning model, etc., select a desired combination of elements for inclusion in data processing pipeline, and submit an imaging processing request. In at least one embodiment, a request may include input data (and associated patient data, in some examples) that is necessary to perform a request, and/or may include a selection of application(s) and/or machine learning models to be executed in processing a request. In at least one embodiment, a request may then be passed to one or more components of deployment system 1206 (e.g., a cloud) to perform processing of data processing pipeline. In at least one embodiment, processing by deployment system 1206 may include referencing selected elements (e.g., applications, containers, models, etc.) from a container registry and/or model registry 1224. In at least one embodiment, once results are generated by a pipeline, results may be returned to a user for reference (e.g., for viewing in a viewing application suite executing on a local, on-premises workstation or terminal).

In at least one embodiment, to aid in processing or execution of applications or containers in pipelines, services 1220 may be leveraged. In at least one embodiment, services 1220 may include compute services, artificial intelligence (AI) services, visualization services, and/or other service types. In at least one embodiment, services 1220 may provide functionality that is common to one or more applications in software 1218, so functionality may be abstracted to a service that may be called upon or leveraged by applications. In at least one embodiment, functionality provided by services 1220 may run dynamically and more efficiently, while also scaling well by allowing applications to process data in parallel (e.g., using a parallel computing platform 1230 (FIG. 12)). In at least one embodiment, rather than each application that shares a same functionality offered by a service 1220 being required to have a respective instance of service 1220, service 1220 may be shared between and among various applications. In at least one embodiment, services may include an inference server or engine that may be used for executing detection or segmentation tasks, as non-limiting examples. In at least one embodiment, a model training service may be included that may provide machine learning model training and/or retraining capabilities. In at least one embodiment, a data augmentation service may further be included that may provide GPU accelerated data (e.g., DICOM, RIS, CIS, REST compliant, RPC, raw, etc.) extraction, resizing, scaling, and/or other augmentation. In at least one embodiment, a visualization service may be used that may add image rendering effects-such as ray-tracing, rasterization, denoising, sharpening, etc.—to add realism to two-dimensional (2D) and/or three-dimensional (3D) models. In at least one embodiment, virtual instrument services may be included that provide for beam-forming, segmentation, inferencing, imaging, and/or support for other applications within pipelines of virtual instruments.

In at least one embodiment, where a service 1220 includes an AI service (e.g., an inference service), one or more machine learning models may be executed by calling upon (e.g., as an API call) an inference service (e.g., an inference server) to execute machine learning model(s), or processing thereof, as part of application execution. In at least one embodiment, where another application includes one or more machine learning models for segmentation tasks, an application may call upon an inference service to execute machine learning models for performing one or more of processing operations associated with segmentation tasks. In at least one embodiment, software 1218 implementing advanced processing and inferencing pipeline that includes segmentation application and anomaly detection application may be streamlined because each application may call upon a same inference service to perform one or more inferencing tasks.

In at least one embodiment, hardware 1222 may include GPUs, CPUs, DPUs, graphics cards, an AI/deep learning system (e.g., an AI supercomputer, such as NVIDIA's DGX), a cloud platform, or a combination thereof. In at least one embodiment, different types of hardware 1222 may be used to provide efficient, purpose-built support for software 1218 and services 1220 in deployment system 1206. In at least one embodiment, use of GPU processing may be implemented for processing locally (e.g., at facility 1202), within an AI/deep learning system, in a cloud system, and/or in other processing components of deployment system 1206 to improve efficiency, accuracy, and efficacy of image processing and generation. In at least one embodiment, software 1218 and/or services 1220 may be optimized for GPU processing with respect to deep learning, machine learning, and/or high-performance computing, as non-limiting examples. In at least one embodiment, at least some of computing environment of deployment system 1206 and/or training system 1204 may be executed in a datacenter one or more supercomputers or high performance computing systems, with GPU optimized software (e.g., hardware and software combination of NVIDIA's DGX System). In at least one embodiment, hardware 1222 may include any number of GPUs that may be called upon to perform processing of data in parallel, as described herein. In at least one embodiment, cloud platform may further include GPU processing for GPU-optimized execution of deep learning tasks, machine learning tasks, or other computing tasks. In at least one embodiment, cloud platform may further include DPU processing to transmit data received over a network and/or through a network controller or other network interface directly to (e.g., a memory of) one or more GPU(s). In at least one embodiment, cloud platform (e.g., NVIDIA's NGC) may be executed using an AI/deep learning supercomputer(s) and/or GPU-optimized software (e.g., as provided on NVIDIA's DGX Systems) as a hardware abstraction and scaling platform. In at least one embodiment, cloud platform may integrate an application container clustering system or orchestration system (e.g., KUBERNETES) on multiple GPUs to enable seamless scaling and load balancing.

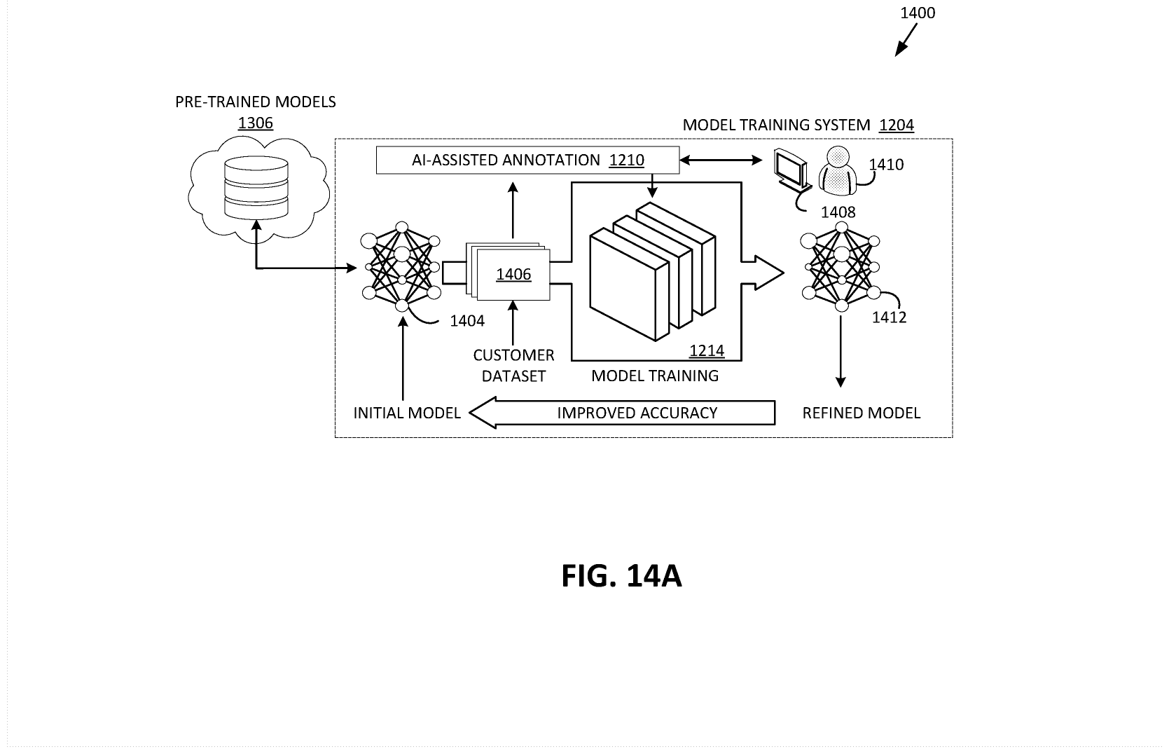

FIG. 13 is a system diagram for an example system 1300 for generating and deploying an imaging deployment pipeline, in accordance with at least one embodiment. In at least one embodiment, system 1300 may be used to implement process 1200 of FIG. 12 and/or other processes including advanced processing and inferencing pipelines. In at least one embodiment, system 1300 may include training system 1204 and deployment system 1206. In at least one embodiment, training system 1204 and deployment system 1206 may be implemented using software 1218, services 1220, and/or hardware 1222, as described herein.

In at least one embodiment, system 1300 (e.g., training system 1204 and/or deployment system 1206) may implemented in a cloud computing environment (e.g., using cloud 1326). In at least one embodiment, system 1300 may be implemented locally with respect to a healthcare services facility, or as a combination of both cloud and local computing resources. In at least one embodiment, access to APIs in cloud 1326 may be restricted to authorized users through enacted security measures or protocols. In at least one embodiment, a security protocol may include web tokens that may be signed by an authentication (e.g., AuthN, AuthZ, Gluecon, etc.) service and may carry appropriate authorization. In at least one embodiment, APIs of virtual instruments (described herein), or other instantiations of system 1300, may be restricted to a set of public IPs that have been vetted or authorized for interaction.

In at least one embodiment, various components of system 1300 may communicate between and among one another using any of a variety of different network types, including but not limited to local area networks (LANs) and/or wide area networks (WANs) via wired and/or wireless communication protocols. In at least one embodiment, communication between facilities and components of system 1300 (e.g., for transmitting inference requests, for receiving results of inference requests, etc.) may be communicated over data bus (ses), wireless data protocols (Wi-Fi), wired data protocols (e.g., Ethernet), etc.

In at least one embodiment, training system 1204 may execute training pipelines 1304, similar to those described herein with respect to FIG. 12. In at least one embodiment, where one or more machine learning models are to be used in deployment pipelines 1310 by deployment system 1206, training pipelines 1304 may be used to train or retrain one or more (e.g., pre-trained) models, and/or implement one or more of pre-trained models 1306 (e.g., without a need for retraining or updating). In at least one embodiment, as a result of training pipelines 1304, output model(s) 1216 may be generated. In at least one embodiment, training pipelines 1304 may include any number of processing steps, such as but not limited to imaging data (or other input data) conversion or adaption In at least one embodiment, for different machine learning models used by deployment system 1206, different training pipelines 1304 may be used. In at least one embodiment, training pipeline 1304 similar to a first example described with respect to FIG. 12 may be used for a first machine learning model, training pipeline 1304 similar to a second example described with respect to FIG. 12 may be used for a second machine learning model, and training pipeline 1304 similar to a third example described with respect to FIG. 12 may be used for a third machine learning model. In at least one embodiment, any combination of tasks within training system 1204 may be used depending on what is required for each respective machine learning model. In at least one embodiment, one or more of machine learning models may already be trained and ready for deployment so machine learning models may not undergo any processing by training system 1204, and may be implemented by deployment system 1206.

In at least one embodiment, output model(s) 1216 and/or pre-trained model(s) 1306 may include any types of machine learning models depending on implementation or embodiment. In at least one embodiment, and without limitation, machine learning models used by system 1300 may include machine learning model(s) using linear regression, logistic regression, decision trees, support vector machines (SVM), Naïve Bayes, k-nearest neighbor (Knn), K means clustering, random forest, dimensionality reduction algorithms, gradient boosting algorithms, neural networks (e.g., auto-encoders, convolutional, recurrent, perceptrons, Long/Short Term Memory (LSTM), Hopfield, Boltzmann, deep belief, deconvolutional, generative adversarial, liquid state machine, etc.), and/or other types of machine learning models.

In at least one embodiment, training pipelines 1304 may include AI-assisted annotation, as described in more detail herein with respect to at least FIG. 12B. In at least one embodiment, labeled data 1212 (e.g., traditional annotation) may be generated by any number of techniques. In at least one embodiment, labels or other annotations may be generated within a drawing program (e.g., an annotation program), a computer aided design (CAD) program, a labeling program, another type of program suitable for generating annotations or labels for ground truth, and/or may be hand drawn, in some examples. In at least one embodiment, ground truth data may be synthetically produced (e.g., generated from computer models or renderings), real produced (e.g., designed and produced from real-world data), machine-automated (e.g., using feature analysis and learning to extract features from data and then generate labels), human annotated (e.g., labeler, or annotation expert, defines location of labels), and/or a combination thereof. In at least one embodiment, for each instance of imaging data 1208 (or other data type used by machine learning models), there may be corresponding ground truth data generated by training system 1204. In at least one embodiment, AI-assisted annotation may be performed as part of deployment pipelines 1310; either in addition to, or in lieu of AI-assisted annotation included in training pipelines 1304. In at least one embodiment, system 1300 may include a multi-layer platform that may include a software layer (e.g., software 1218) of diagnostic applications (or other application types) that may perform one or more medical imaging and diagnostic functions. In at least one embodiment, system 1300 may be communicatively coupled to (e.g., via encrypted links) PACS server networks of one or more facilities. In at least one embodiment, system 1300 may be configured to access and referenced data from PACS servers to perform operations, such as training machine learning models, deploying machine learning models, image processing, inferencing, and/or other operations.

In at least one embodiment, a software layer may be implemented as a secure, encrypted, and/or authenticated API through which applications or containers may be invoked (e.g., called) from an external environment(s) (e.g., facility 1202). In at least one embodiment, applications may then call or execute one or more services 1220 for performing compute, AI, or visualization tasks associated with respective applications, and software 1218 and/or services 1220 may leverage hardware 1222 to perform processing tasks in an effective and efficient manner.

In at least one embodiment, deployment system 1206 may execute deployment pipelines 1310. In at least one embodiment, deployment pipelines 1310 may include any number of applications that may be sequentially, non-sequentially, or otherwise applied to imaging data (and/or other data types) generated by imaging devices, sequencing devices, genomics devices, etc.—including AI-assisted annotation, as described above. In at least one embodiment, as described herein, a deployment pipeline 1310 for an individual device may be referred to as a virtual instrument for a device (e.g., a virtual ultrasound instrument, a virtual CT scan instrument, a virtual sequencing instrument, etc.). In at least one embodiment, for a single device, there may be more than one deployment pipeline 1310 depending on information desired from data generated by a device. In at least one embodiment, where detections of anomalies are desired from an MRI machine, there may be a first deployment pipeline 1310, and where image enhancement is desired from output of an MRI machine, there may be a second deployment pipeline 1310.

In at least one embodiment, an image generation application may include a processing task that includes use of a machine learning model. In at least one embodiment, a user may desire to use their own machine learning model, or to select a machine learning model from model registry 1224. In at least one embodiment, a user may implement their own machine learning model or select a machine learning model for inclusion in an application for performing a processing task. In at least one embodiment, applications may be selectable and customizable, and by defining constructs of applications, deployment, and implementation of applications for a particular user are presented as a more seamless user experience. In at least one embodiment, by leveraging other features of system 1300—such as services 1220 and hardware 1222—deployment pipelines 1310 may be even more user friendly, provide for easier integration, and produce more accurate, efficient, and timely results. One or more embodiments of the application may be implemented as, or to include a game, a video streaming application, a machine control application, a machine locomotion application, a machine driving application, a synthetic data generation application, a model training application, a perception application, an augmented reality application, a virtual reality application, a mixed reality application, a robotics application, a security and surveillance application, an autonomous or semi-autonomous machine application, a deep learning application, an environment simulation application, a data center processing application, a conversational AI application, a light transport simulation application (e.g., ray tracing, path tracing, etc.), a collaborative content creation application for 3D assets, a digital twin system application, a cloud computing application and/or another type of application or service.

In at least one embodiment, deployment system 1206 may include a user interface 1314 (e.g., a graphical user interface, a web interface, etc.) that may be used to select applications for inclusion in deployment pipeline(s) 1310, arrange applications, modify, or change applications or parameters or constructs thereof, use and interact with deployment pipeline(s) 1310 during set-up and/or deployment, and/or to otherwise interact with deployment system 1206. In at least one embodiment, although not illustrated with respect to training system 1204, user interface 1314 (or a different user interface) may be used for selecting models for use in deployment system 1206, for selecting models for training, or retraining, in training system 1204, and/or for otherwise interacting with training system 1204.

In at least one embodiment, pipeline manager 1312 may be used, in addition to an application orchestration system 1328, to manage interaction between applications or containers of deployment pipeline(s) 1310 and services 1220 and/or hardware 1222. In at least one embodiment, pipeline manager 1312 may be configured to facilitate interactions from application to application, from application to service 1220, and/or from application or service to hardware 1222. In at least one embodiment, although illustrated as included in software 1218, this is not intended to be limiting, and in some examples (e.g., as illustrated in FIG. 11) pipeline manager 1312 may be included in services 1220. In at least one embodiment, application orchestration system 1328 (e.g., Kubernetes, DOCKER, etc.) may include a container orchestration system that may group applications into containers as logical units for coordination, management, scaling, and deployment. In at least one embodiment, by associating applications from deployment pipeline(s) 1310 (e.g., a reconstruction application, a segmentation application, etc.) with individual containers, each application may execute in a self-contained environment (e.g., at a kernel level) to increase speed and efficiency.

In at least one embodiment, each application and/or container (or image thereof) may be individually developed, modified, and deployed (e.g., a first user or developer may develop, modify, and deploy a first application and a second user or developer may develop, modify, and deploy a second application separate from a first user or developer), which may allow for focus on, and attention to, a task of a single application and/or container(s) without being hindered by tasks of another application(s) or container(s). In at least one embodiment, communication, and cooperation between different containers or applications may be aided by pipeline manager 1312 and application orchestration system 1328. In at least one embodiment, so long as an expected input and/or output of each container or application is known by a system (e.g., based on constructs of applications or containers), application orchestration system 1328 and/or pipeline manager 1312 may facilitate communication among and between, and sharing of resources among and between, each of applications or containers. In at least one embodiment, because one or more of applications or containers in deployment pipeline(s) 1310 may share same services and resources, application orchestration system 1328 may orchestrate, load balance, and determine sharing of services or resources between and among various applications or containers. In at least one embodiment, a scheduler may be used to track resource requirements of applications or containers, current usage or planned usage of these resources, and resource availability. In at least one embodiment, a scheduler may thus allocate resources to different applications and distribute resources between and among applications in view of requirements and availability of a system. In some examples, a scheduler (and/or other component of application orchestration system 1328) may determine resource availability and distribution based on constraints imposed on a system (e.g., user constraints), such as quality of service (QOS), urgency of need for data outputs (e.g., to determine whether to execute real-time processing or delayed processing), etc.

In at least one embodiment, services 1220 leveraged by and shared by applications or containers in deployment system 1206 may include compute services 1316, AI services 1318, visualization services 1320, and/or other service types. In at least one embodiment, applications may call (e.g., execute) one or more of services 1220 to perform processing operations for an application. In at least one embodiment, compute services 1316 may be leveraged by applications to perform super-computing or other high-performance computing (HPC) tasks. In at least one embodiment, compute service(s) 1316 may be leveraged to perform parallel processing (e.g., using a parallel computing platform 1330) for processing data through one or more of applications and/or one or more tasks of a single application, substantially simultaneously. In at least one embodiment, parallel computing platform 1330 (e.g., NVIDIA's CUDA) may enable general purpose computing on GPUs (GPGPU) (e.g., GPUs 1322). In at least one embodiment, a software layer of parallel computing platform 1330 may provide access to virtual instruction sets and parallel computational elements of GPUs, for execution of compute kernels. In at least one embodiment, parallel computing platform 1330 may include memory and, in some embodiments, a memory may be shared between and among multiple containers, and/or between and among different processing tasks within a single container. In at least one embodiment, inter-process communication (IPC) calls may be generated for multiple containers and/or for multiple processes within a container to use same data from a shared segment of memory of parallel computing platform 1330 (e.g., where multiple different stages of an application or multiple applications are processing same information). In at least one embodiment, rather than making a copy of data and moving data to different locations in memory (e.g., a read/write operation), same data in same location of a memory may be used for any number of processing tasks (e.g., at a same time, at different times, etc.). In at least one embodiment, as data is used to generate new data as a result of processing, this information of a new location of data may be stored and shared between various applications. In at least one embodiment, location of data and a location of updated or modified data may be part of a definition of how a payload is understood within containers.

In at least one embodiment, AI services 1318 may be leveraged to perform inferencing services for executing machine learning model(s) associated with applications (e.g., tasked with performing one or more processing tasks of an application). In at least one embodiment, AI services 1318 may leverage AI system 1324 to execute machine learning model(s) (e.g., neural networks, such as CNNs) for segmentation, reconstruction, object detection, feature detection, classification, and/or other inferencing tasks. In at least one embodiment, applications of deployment pipeline(s) 1310 may use one or more of output models 1216 from training system 1204 and/or other models of applications to perform inference on imaging data. In at least one embodiment, two or more examples of inferencing using application orchestration system 1328 (e.g., a scheduler) may be available. In at least one embodiment, a first category may include a high priority/low latency path that may achieve higher service level agreements, such as for performing inference on urgent requests during an emergency, or for a radiologist during diagnosis. In at least one embodiment, a second category may include a standard priority path that may be used for requests that may be non-urgent or where analysis may be performed at a later time. In at least one embodiment, application orchestration system 1328 may distribute resources (e.g., services 1220 and/or hardware 1222) based on priority paths for different inferencing tasks of AI services 1318.

In at least one embodiment, shared storage may be mounted to AI services 1318 within system 1300. In at least one embodiment, shared storage may operate as a cache (or other storage device type) and may be used to process inference requests from applications. In at least one embodiment, when an inference request is submitted, a request may be received by a set of API instances of deployment system 1206, and one or more instances may be selected (e.g., for best fit, for load balancing, etc.) to process a request. In at least one embodiment, to process a request, a request may be entered into a database, a machine learning model may be located from model registry 1224 if not already in a cache, a validation step may ensure appropriate machine learning model is loaded into a cache (e.g., shared storage), and/or a copy of a model may be saved to a cache. In at least one embodiment, a scheduler (e.g., of pipeline manager 1312) may be used to launch an application that is referenced in a request if an application is not already running or if there are not enough instances of an application. In at least one embodiment, if an inference server is not already launched to execute a model, an inference server may be launched. Any number of inference servers may be launched per model. In at least one embodiment, in a pull model, in which inference servers are clustered, models may be cached whenever load balancing is advantageous. In at least one embodiment, inference servers may be statically loaded in corresponding, distributed servers.

In at least one embodiment, inferencing may be performed using an inference server that runs in a container. In at least one embodiment, an instance of an inference server may be associated with a model (and optionally a plurality of versions of a model). In at least one embodiment, if an instance of an inference server does not exist when a request to perform inference on a model is received, a new instance may be loaded. In at least one embodiment, when starting an inference server, a model may be passed to an inference server such that a same container may be used to serve different models so long as inference server is running as a different instance.

In at least one embodiment, during application execution, an inference request for a given application may be received, and a container (e.g., hosting an instance of an inference server) may be loaded (if not already), and a start procedure may be called. In at least one embodiment, pre-processing logic in a container may load, decode, and/or perform any additional pre-processing on incoming data (e.g., using a CPU(s) and/or GPU(s) and/or DPU(s)). In at least one embodiment, once data is prepared for inference, a container may perform inference as necessary on data. In at least one embodiment, this may include a single inference call on one image (e.g., a hand X-ray), or may require inference on hundreds of images (e.g., a chest CT). In at least one embodiment, an application may summarize results before completing, which may include, without limitation, a single confidence score, pixel level-segmentation, voxel-level segmentation, generating a visualization, or generating text to summarize findings. In at least one embodiment, different models or applications may be assigned different priorities. For example, some models may have a real-time (TAT<1 min) priority while others may have lower priority (e.g., TAT<12 min). In at least one embodiment, model execution times may be measured from requesting institution or entity and may include partner network traversal time, as well as execution on an inference service.

In at least one embodiment, transfer of requests between services 1220 and inference applications may be hidden behind a software development kit (SDK), and robust transport may be provided through a queue. In at least one embodiment, a request will be placed in a queue via an API for an individual application/tenant ID combination and an SDK will pull a request from a queue and give a request to an application. In at least one embodiment, a name of a queue may be provided in an environment from where an SDK will pick it up. In at least one embodiment, asynchronous communication through a queue may be useful as it may allow any instance of an application to pick up work as it becomes available. Results may be transferred back through a queue, to ensure no data is lost. In at least one embodiment, queues may also provide an ability to segment work, as highest priority work may go to a queue with most instances of an application connected to it, while lowest priority work may go to a queue with a single instance connected to it that processes tasks in an order received. In at least one embodiment, an application may run on a GPU-accelerated instance generated in cloud 1326, and an inference service may perform inferencing on a GPU.

In at least one embodiment, visualization services 1320 may be leveraged to generate visualizations for viewing outputs of applications and/or deployment pipeline(s) 1310. In at least one embodiment, GPUs 1322 may be leveraged by visualization services 1320 to generate visualizations. In at least one embodiment, rendering effects, such as ray-tracing, may be implemented by visualization services 1320 to generate higher quality visualizations. In at least one embodiment, visualizations may include, without limitation, 2D image renderings, 3D volume renderings, 3D volume reconstruction, 2D tomographic slices, virtual reality displays, augmented reality displays, etc. In at least one embodiment, virtualized environments may be used to generate a virtual interactive display or environment (e.g., a virtual environment) for interaction by users of a system (e.g., doctors, nurses, radiologists, etc.). In at least one embodiment, visualization services 1320 may include an internal visualizer, cinematics, and/or other rendering or image processing capabilities or functionality (e.g., ray tracing, rasterization, internal optics, etc.).

In at least one embodiment, hardware 1222 may include GPUs 1322, AI system 1324, cloud 1326, and/or any other hardware used for executing training system 1204 and/or deployment system 1606. In at least one embodiment, GPUs 1322 (e.g., NVIDIA's TESLA and/or QUADRO GPUs) may include any number of GPUs that may be used for executing processing tasks of compute services 1316, AI services 1318, visualization services 1320, other services, and/or any of features or functionality of software 1218. For example, with respect to AI services 1318, GPUs 1322 may be used to perform pre-processing on imaging data (or other data types used by machine learning models), post-processing on outputs of machine learning models, and/or to perform inferencing (e.g., to execute machine learning models). In at least one embodiment, cloud 1326, AI system 1324, and/or other components of system 1300 may use GPUs 1322. In at least one embodiment, cloud 1326 may include a GPU-optimized platform for deep learning tasks. In at least one embodiment, AI system 1324 may use GPUs, and cloud 1326—or at least a portion tasked with deep learning or inferencing—may be executed using one or more AI systems 1324. As such, although hardware 1222 is illustrated as discrete components, this is not intended to be limiting, and any components of hardware 1222 may be combined with, or leveraged by, any other components of hardware 1222.

In at least one embodiment, AI system 1324 may include a purpose-built computing system (e.g., a super-computer or an HPC) configured for inferencing, deep learning, machine learning, and/or other artificial intelligence tasks. In at least one embodiment, AI system 1324 (e.g., NVIDIA's DGX) may include GPU-optimized software (e.g., a software stack) that may be executed using a plurality of GPUs 1322, in addition to DPUs, CPUs, RAM, storage, and/or other components, features, or functionality. In at least one embodiment, one or more AI systems 1324 may be implemented in cloud 1326 (e.g., in a data center) for performing some or all of AI-based processing tasks of system 1300.

In at least one embodiment, cloud 1326 may include a GPU-accelerated infrastructure (e.g., NVIDIA's NGC) that may provide a GPU-optimized platform for executing processing tasks of system 1300. In at least one embodiment, cloud 1326 may include an AI system(s) 1324 for performing one or more of AI-based tasks of system 1300 (e.g., as a hardware abstraction and scaling platform). In at least one embodiment, cloud 1326 may integrate with application orchestration system 1328 leveraging multiple GPUs to enable seamless scaling and load balancing between and among applications and services 1220. In at least one embodiment, cloud 1326 may tasked with executing at least some of services 1220 of system 1300, including compute services 1316, AI services 1318, and/or visualization services 1320, as described herein. In at least one embodiment, cloud 1326 may perform small and large batch inference (e.g., executing NVIDIA's TENSOR RT), provide an accelerated parallel computing API and platform 1330 (e.g., NVIDIA's CUDA), execute application orchestration system 1328 (e.g., KUBERNETES), provide a graphics rendering API and platform (e.g., for ray-tracing, 2D graphics, 3D graphics, and/or other rendering techniques to produce higher quality cinematics), and/or may provide other functionality for system 1300.

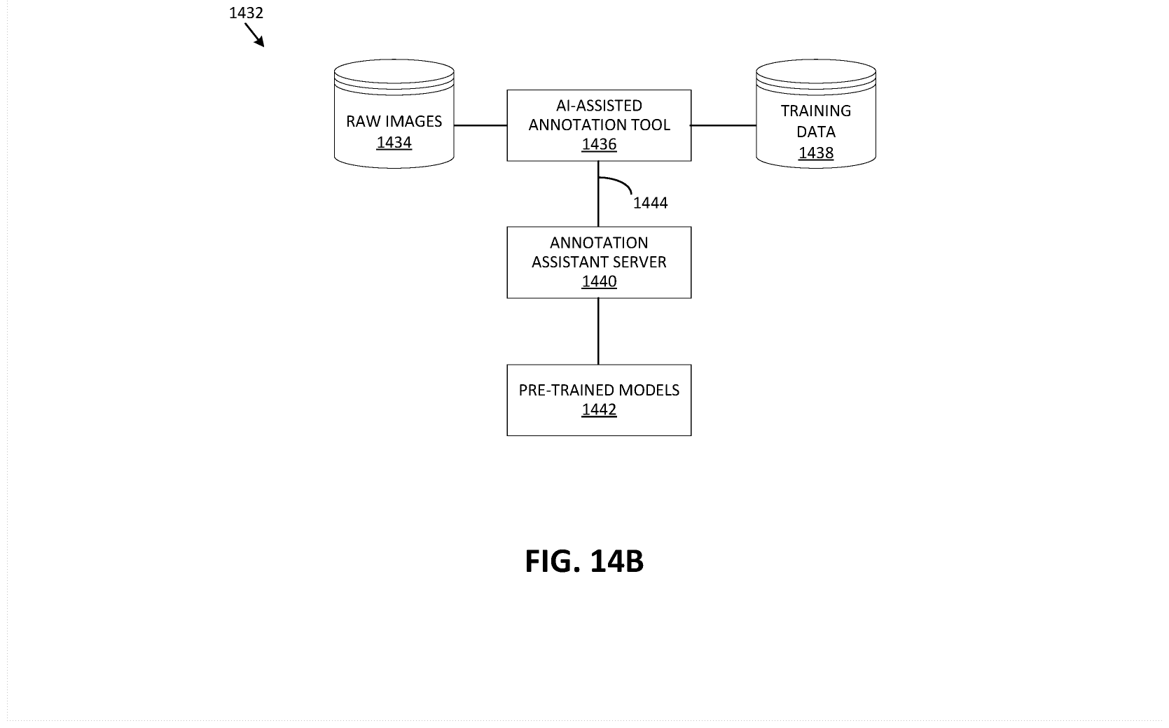

FIG. 14A illustrates a data flow diagram for a process 1400 to train, retrain, or update a machine learning model, in accordance with at least one embodiment. In at least one embodiment, process 1400 may be executed using, as a non-limiting example, system 1300 of FIG. 13. In at least one embodiment, process 1400 may leverage services 1220 and/or hardware 1222 of system 1300, as described herein. In at least one embodiment, refined models 1412 generated by process 1400 may be executed by deployment system 1206 for one or more containerized applications in deployment pipelines 1310.

In at least one embodiment, model training 1214 may include retraining or updating an initial model 1404 (e.g., a pre-trained model) using new training data (e.g., new input data, such as customer dataset 1406, and/or new ground truth data associated with input data). In at least one embodiment, to retrain, or update, initial model 1404, output or loss layer(s) of initial model 1404 may be reset, or deleted, and/or replaced with an updated or new output or loss layer(s). In at least one embodiment, initial model 1404 may have previously fine-tuned parameters (e.g., weights and/or biases) that remain from prior training, so training or retraining 1214 may not take as long or require as much processing as training a model from scratch. In at least one embodiment, during model training 1214, by having reset or replaced output or loss layer(s) of initial model 1404, parameters may be updated and re-tuned for a new data set based on loss calculations associated with accuracy of output or loss layer(s) at generating predictions on new, customer dataset 1406 (e.g., image data 1208 of FIG. 12).

In at least one embodiment, pre-trained models 1306 may be stored in a data store, or registry (e.g., model registry 1224 of FIG. 12). In at least one embodiment, pre-trained models 1306 may have been trained, at least in part, at one or more facilities other than a facility executing process 1400. In at least one embodiment, to protect privacy and rights of patients, subjects, or clients of different facilities, pre-trained models 1306 may have been trained, on-premise, using customer or patient data generated on-premise. In at least one embodiment, pre-trained models 1306 may be trained using cloud 1326 and/or other hardware 1222, but confidential, privacy protected patient data may not be transferred to, used by, or accessible to any components of cloud 1326 (or other off premise hardware). In at least one embodiment, where a pre-trained model 1306 is trained at using patient data from more than one facility, pre-trained model 1306 may have been individually trained for each facility prior to being trained on patient or customer data from another facility. In at least one embodiment, such as where a customer or patient data has been released of privacy concerns (e.g., by waiver, for experimental use, etc.), or where a customer or patient data is included in a public data set, a customer or patient data from any number of facilities may be used to train pre-trained model 1306 on-premise and/or off premise, such as in a datacenter or other cloud computing infrastructure.

In at least one embodiment, when selecting applications for use in deployment pipelines 1310, a user may also select machine learning models to be used for specific applications. In at least one embodiment, a user may not have a model for use, so a user may select a pre-trained model 1306 to use with an application. In at least one embodiment, pre-trained model 1306 may not be optimized for generating accurate results on customer dataset 1406 of a facility of a user (e.g., based on patient diversity, demographics, types of medical imaging devices used, etc.). In at least one embodiment, prior to deploying pre-trained model 1306 into deployment pipeline 1310 for use with an application(s), pre-trained model 1306 may be updated, retrained, and/or fine-tuned for use at a respective facility.

In at least one embodiment, a user may select pre-trained model 1306 that is to be updated, retrained, and/or fine-tuned, and pre-trained model 1306 may be referred to as initial model 1404 for training system 1204 within process 1400. In at least one embodiment, customer dataset 1406 (e.g., imaging data, genomics data, sequencing data, or other data types generated by devices at a facility) may be used to perform model training 1214 (which may include, without limitation, transfer learning) on initial model 1404 to generate refined model 1412. In at least one embodiment, ground truth data corresponding to customer dataset 1406 may be generated by training system 1204. In at least one embodiment, ground truth data may be generated, at least in part, by clinicians, scientists, doctors, practitioners, at a facility (e.g., as labeled clinic data 1212 of FIG. 12).

In at least one embodiment, AI-assisted annotation 1210 may be used in some examples to generate ground truth data. In at least one embodiment, AI-assisted annotation 1210 (e.g., implemented using an AI-assisted annotation SDK) may leverage machine learning models (e.g., neural networks) to generate suggested or predicted ground truth data for a customer dataset. In at least one embodiment, user 1410 may use annotation tools within a user interface (a graphical user interface (GUI)) on computing device 1408.

In at least one embodiment, user 1410 may interact with a GUI via computing device 1408 to edit or fine-tune (auto) annotations. In at least one embodiment, a polygon editing feature may be used to move vertices of a polygon to more accurate or fine-tuned locations.

In at least one embodiment, once customer dataset 1406 has associated ground truth data, ground truth data (e.g., from AI-assisted annotation, manual labeling, etc.) may be used by during model training 1214 to generate refined model 1412. In at least one embodiment, customer dataset 1406 may be applied to initial model 1404 any number of times, and ground truth data may be used to update parameters of initial model 1404 until an acceptable level of accuracy is attained for refined model 1412. In at least one embodiment, once refined model 1412 is generated, refined model 1412 may be deployed within one or more deployment pipelines 1210 at a facility for performing one or more processing tasks with respect to medical imaging data.

In at least one embodiment, refined model 1412 may be uploaded to pre-trained models 1206 in model registry 1224 to be selected by another facility. In at least one embodiment, his process may be completed at any number of facilities such that refined model 1412 may be further refined on new datasets any number of times to generate a more universal model.

FIG. 14B is an example illustration of a client-server architecture 1432 to enhance annotation tools with pre-trained annotation models, in accordance with at least one embodiment. In at least one embodiment, AI-assisted annotation tools 1436 may be instantiated based on a client-server architecture 1432. In at least one embodiment, annotation tools 1436 in imaging applications may aid radiologists, for example, identify organs and abnormalities. In at least one embodiment, imaging applications may include software tools that help user 1410 to identify, as a non-limiting example, a few extreme points on a particular organ of interest in raw images 1434 (e.g., in a 3D MRI or CT scan) and receive auto-annotated results for all 2D slices of a particular organ. In at least one embodiment, results may be stored in a data store as training data 1438 and used as (for example and without limitation) ground truth data for training. In at least one embodiment, when computing device 1408 sends extreme points for AI-assisted annotation 1210, a deep learning model, for example, may receive this data as input and return inference results of a segmented organ or abnormality. In at least one embodiment, pre-instantiated annotation tools, such as AI-Assisted Annotation Tool 1436B in FIG. 14B, may be enhanced by making API calls (e.g., API Call 1444) to a server, such as an Annotation Assistant Server 1440 that may include a set of pre-trained models 1442 stored in an annotation model registry, for example. In at least one embodiment, an annotation model registry may store pre-trained models 1442 (e.g., machine learning models, such as deep learning models) that are pre-trained to perform AI-assisted annotation on a particular organ or abnormality. These models may be further updated by using training pipelines 1304. In at least one embodiment, pre-installed annotation tools may be improved over time as new labeled clinic data 1212 is added.

Such components may be used to generate synthetic data imitating failure cases in a network training process, which may help to improve performance of the network while limiting the amount of synthetic data to avoid overfitting.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit the disclosure to a specific form or forms disclosed, but on the contrary, the intention is to cover all modifications, alternative constructions, and equivalents falling within the spirit and scope of the disclosure, as defined in appended claims.

Use of terms “a” and “an” and “the” and similar referents in the context of describing disclosed embodiments (especially in the context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitations of ranges of values herein are merely intended to serve as a shorthand method of referring individually to each separate value falling within the range, unless otherwise indicated herein, and each separate value is incorporated into the specification as if it were individually recited herein. In at least one embodiment, the use of the term “set” (e.g., “a set of items”) or “subset” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but subset and corresponding set may be equal.

Conjunctive language, such as phrases of the form “at least one of A, B, and C,” or “at least one of A, B and C,” unless specifically stated otherwise or otherwise clearly contradicted by context, is otherwise understood with the context as used in general to present that an item, term, etc., may be either A or B or C, or any nonempty subset of the set of A and B and C. For instance, in an illustrative example of a set having three members, conjunctive phrases “at least one of A, B, and C” and “at least one of A, B and C” refer to any of the following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, the term “plurality” indicates a state of being plural (e.g., “a plurality of items” indicates multiple items). In at least one embodiment, the number of items in a plurality is at least two, but can be more when so indicated either explicitly or by context. Further, unless stated otherwise or otherwise clear from context, the phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in the form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause a computer system to perform operations described herein. In at least one embodiment, a set of non-transitory computer-readable storage media comprises multiple non-transitory computer-readable storage media and one or more of individual non-transitory storage media of multiple non-transitory computer-readable storage media lack all of the code while multiple non-transitory computer-readable storage media collectively store all of the code. In at least one embodiment, executable instructions are executed such that different instructions are executed by different processors.

Accordingly, in at least one embodiment, computer systems are configured to implement one or more services that singly or collectively perform operations of processes described herein and such computer systems are configured with applicable hardware and/or software that enable the performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

All references, including publications, patent applications, and patents, cited herein are hereby incorporated by reference to the same extent as if each reference were individually and specifically indicated to be incorporated by reference and were set forth in its entirety herein.

In description and claims, terms “coupled” and “connected,” along with their derivatives, may be used. It should be understood that these terms may not be intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, the term “processor” may refer to any device or portion of a device that processes electronic data from registers and/or memory and transform that electronic data into other electronic data that may be stored in registers and/or memory. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as the system may embody one or more methods and methods may be considered a system.

In the present document, references may be made to obtaining, acquiring, receiving, or inputting analog or digital data into a subsystem, computer system, or computer-implemented machine. In at least one embodiment, the process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface or inter-process communication mechanism.

Although descriptions herein set forth example embodiments of described techniques, other architectures may be used to implement described functionality, and are intended to be within the scope of this disclosure. Furthermore, although specific distributions of responsibilities may be defined above for purposes of description, various functions and responsibilities might be distributed and divided in different ways, depending on circumstances.

Furthermore, although the subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A method comprising:
receiving, by a three-dimensional (3D) graphics platform, user reaction data from one or more user devices associated with a user of the 3D graphics platform, wherein the user reaction data indicates a reaction of the user to a simulation provided via at least one of the one or more user devices;
providing, by the 3D graphics platform, the user reaction data as input to an artificial intelligence (AI) model;
determining, by the 3D graphics platform and based on one or more outputs of the AI model, simulation update data comprising an indication of one or more updates to the simulation based on an experience of the user in view of the provided user reaction data; and
updating, by the 3D graphics platform, a model file associated with the simulation to reflect the one or more updates to the simulation as indicated by the simulation update data, wherein the updated model file, when executed, creates a rendering of the updated simulation.

2. The method of claim 1, wherein at least one of the simulation update data or the updated model file is associated with a universal scene description (USD) format.

3. The method of claim 1, wherein the user reaction data comprises at least one of facial reaction data, body language data, heart rate data, breathing rate data, or speech pattern data.

4. The method of claim 1, wherein the one or more updates to the simulation comprise at least one of an audio update, a visual update, a virtual avatar manipulation, an object manipulation, or a virtual environment manipulation.

5. The method of claim 1, wherein updating the model file associated with the simulation to reflect the one or more updates to the simulation comprises:
providing the determined simulation update data as input to a second AI model; and
obtaining, using one or more outputs of the second AI model, the updated model file associated with the simulation.

6. The method of claim 5, further comprising:
obtaining an initial model file associated with the simulation; and
providing the initial model file associated with the simulation with the determined simulation update data as input into the second AI model.

7. The method of claim 6, wherein the second AI model is a generative AI model, and wherein at least a portion of the updated model file, when executed, renders an updated environment of the simulation, as generated by the generative AI model.

8. The method of claim 1, further comprising:
identifying simulation target data associated with the simulation provided via the at least one of the one or more user devices, wherein the simulation target data indicates one or more targets of the simulation with respect to an experience of the user; and
providing the identified simulation target data with the user reaction data as input to the AI model.

9. The method of claim 8, further comprising:
determining a simulation progress level associated with the user based on the received user reaction data; and
updating the simulation target data associated with the simulation based on the determined simulation progress level.

10. The method of claim 1, wherein the AI model is trained based on historical data associated with the at least one of the one or more user devices.

11. The method of claim 1, wherein the AI model is trained based on historical data associated with a set of other user devices associated with other users of the platform.

12. The method of claim 1, further comprising:
providing, by the 3D graphics platform, the updated simulation to the user via at least one of the one or more users devices based on an execution of the updated model file.

13. A system comprising:
a memory device; and
a processing device coupled to the memory device, the processing device to perform operations comprising:
receiving, by a three-dimensional (3D) graphics platform, user reaction data from one or more user devices associated with a user of the 3D graphics platform, wherein the user reaction data indicates a reaction of the user to a simulation provided via at least one of the one or more user devices;
providing, by the 3D graphics platform, the user reaction data as input to an artificial intelligence (AI) model;
determining, by the 3D graphics platform and based on one or more outputs of the AI model, simulation update data comprising an indication of one or more updates to the simulation based on an experience of the user in view of the provided user reaction data; and
updating, by the 3D graphics platform, a model file associated with the simulation to reflect the one or more updates to the simulation as indicated by the simulation update data, wherein the updated model file, when executed, creates a rendering of the updated simulation.

14. The system of claim 13, wherein at least one of the simulation update data or the updated model file is associated with a universal scene description (USD) format.

15. The system of claim 13, wherein the user reaction data comprises at least one of facial reaction data, body language data, heart rate data, breathing rate data, or speech pattern data.

16. The system of claim 13, wherein the one or more updates to the simulation comprise at least one of an audio update, a visual update, a virtual avatar manipulation, an object manipulation, or a virtual environment manipulation.

17. The system of claim 13, wherein updating the model file associated with the simulation to reflect the one or more updates to the simulation comprises:
providing the determined simulation update data as input to a second AI model; and
extracting from one or more outputs of the second AI model, the updated model file associated with the simulation.

18. The system of claim 17, wherein the operations further comprise:
obtaining an initial model file associated with the simulation; and
providing the initial model file associated with the simulation with the determined simulation update data as input into the second AI model.

19. A non-transitory computer readable medium that stores instructions that, when executed by a processing device, perform operations comprising:
receiving, by a three-dimensional (3D) graphics platform, user reaction data from one or more user devices associated with a user of the 3D graphics platform, wherein the user reaction data indicates a reaction of the user to a simulation provided via at least one of the one or more user devices;
providing, by the 3D graphics platform, the user reaction data as input to an artificial intelligence (AI) model;
determining, by the 3D graphics platform and based on one or more outputs of the AI model, simulation update data comprising an indication of one or more updates to the simulation based on an experience of the user in view of the provided user reaction data; and
updating, by the 3D graphics platform, a model file associated with the simulation to reflect the one or more updates to the simulation as indicated by the simulation update data, wherein the updated model file, when executed, creates a rendering of the updated simulation.

20. The non-transitory computer readable medium of claim 19, wherein at least one of the simulation update data or the updated model file is associated with a universal scene description (USD) format.
